(19) United States
(12) Patent Application Publication
(10) Pub. No.: US 2026/0293454 A1
(43) Pub. Date: Sep. 24, 2026

(54) DISPLAY DEVICE AND ELECTRONIC DEVICE INCLUDING THE SAME

(71) Applicant: Samsung Display Co., Ltd., Yongin-si (KR)

(72) Inventor: Jong Hyun CHOI, Yongin-si (KR)

(21) Appl. No.: 19/352,175

(22) Filed: Oct. 7, 2025

(30) Foreign Application Priority Data
Mar. 19, 2025 (KR) 10-2025-0035382

(51) Int. Cl. H10K 59/126; H10K 59/131; H10K 59/80

(52) U.S. Cl. CPC H10K 59/126; H10K 59/131; H10K 59/873

(57) ABSTRACT

A display device includes: a first substrate; a second substrate; and a filling layer. Each of the first and second substrates include: a display area; a non-display area around the display area; a light transmitting area; and a light transmitting peripheral area. The first substrate further includes: a circuit layer on a support substrate; and two or more light transmitting peripheral dams in the light transmitting peripheral area. The circuit layer includes: light emitting pixel drivers; data lines to transmit data signals to the light emitting pixel drivers; and a shield line in the light emitting peripheral area, to transmit a constant voltage, and overlapping with some of the data lines. The two or more light transmitting peripheral dams overlap with the shield line.

### CROSS-REFERENCE TO RELATED APPLICATION

The present application claims priority to and the benefit of Korean Patent Application No. 10-2025-0035382, filed on Mar. 19, 2025, in the Korean Intellectual Property Office, the entire disclosure of which is incorporated by reference herein.

### BACKGROUND

### 1. Field

Aspects of embodiments of the present disclosure relate to a display device, and an electronic device including the display device.

### 2. Description of the Related Art

With the advancement of information-oriented society, more and more demand is being placed on display devices for displaying images in various ways. For example, display devices are employed in various suitable electronic devices, such as smartphones, digital cameras, laptop computers, navigation devices, and smart televisions.

A display device may be a flat panel display device, such as a liquid crystal display device, a field emission display device, and a light emitting display device. Examples of the light emitting display device may include an organic light emitting display device including organic light emitting elements, an inorganic light emitting display device including inorganic light emitting elements such as inorganic semiconductors, and a micro light emitting display device including micro light emitting elements.

The organic light emitting display device displays an image using the organic light emitting elements, each including a light emitting layer containing an organic light emitting material. The organic light emitting display device implements an image display using a self-light emitting element, and thus, may have relatively superior performance in a power consumption, response speeds, a luminous efficiency, a luminance, and a wide viewing angle compared to those of other display devices.

In a display device, a display surface from which light is emitted may include a display area in which an image is displayed, and a non-display area around the display area. Emission areas for emitting light with respective luminances and colors may be arranged in the display area.

The above information disclosed in this Background section is for enhancement of understanding of the background of the present disclosure, and therefore, it may contain information that does not constitute prior art.

### SUMMARY

A display device may include a first substrate and a second substrate that face each other and are bonded together to improve a strength, and a filling layer filled between the first substrate and the second substrate.

An optical device located below a light transmitting area of the display device may perform a sensing operation for detecting light transmitted through the display device.

Accordingly, in order to improve an amount of light (hereinafter also referred to as a "light transmission rate") transmitted to the optical device by passing through the light transmitting area of the display device, each of some wires among the wires of the display device, which cross or intersect the light transmitting area, may include a bypass line that bypasses the light transmitting area.

However, because the bypass lines of some lines crossing or intersecting the light transmitting area may be arranged to be adjacent to each other in a limited area, a coupling defect between the bypass lines may easily occur.

Embodiments of the present disclosure may be directed to a display device capable of reducing a coupling defect between bypass lines, and an electronic device including the display device.

However, the present disclosure is not limited to the above aspects and features. The above and other aspects and features of the present disclosure will become more apparent to those having ordinary skill in the art by referencing the below description.

According to one or more embodiments of the present disclosure, a display device includes: a first substrate; a second substrate facing and bonded to the first substrate, each of the first substrate and the second substrate including: a display area including emission areas; a non-display area around the display area; a light transmitting area surrounded around by the display area; and a light transmitting peripheral area between the light transmitting area and the display area; and a filling layer filled between the first substrate and the second substrate. The first substrate further includes: a support substrate; a circuit layer on the support substrate; and two or more light transmitting peripheral dams in the light transmitting peripheral area, and spaced from each other. The circuit layer includes: light emitting pixel drivers along a first direction and a second direction in the display area; data lines extending in the second direction, and configured to transmit data signals to the light emitting pixel drivers; and a shield line in the light emitting peripheral area, configured to transmit a constant voltage, and overlapping with some of the data lines in a third direction. The two or more light transmitting peripheral dams overlap with the shield line in the third direction.

In an embodiment, the data lines may include: intersecting data lines, each including: a bypass data line overlapping with the light emitting peripheral area; a first divided data line facing one side of the light transmitting peripheral area in the second direction; and a second divided data line facing another side of the light transmitting peripheral area in the second direction, and electrically connected to the first divided data line through the bypass data line; and normal data lines spaced from the light transmitting area and the light transmitting peripheral area in the first direction. The shield line may be located between the bypass data lines of the intersecting data lines and the two or more light transmitting peripheral dams in the third direction.

In an embodiment, the first substrate may further include: an element layer on the circuit layer; an encapsulation layer covering the element layer; and a light transmitting hole overlapping with the light transmitting area. The element layer may include: first electrodes in the emission areas, and electrically connected to the light emitting pixel drivers, respectively; a pixel defining layer in a non-emission area between the emission areas of the display area, and covering edges of the first electrodes; first common layers on the first electrodes; light emitting layers on the first common layers; a second common layer on the pixel defining layer and the light emitting layers; and a second electrode on the second common layer. The encapsulation layer may include: a first encapsulation layer on the element layer, and including an inorganic insulating material; a second encapsulation layer on the first encapsulation layer, and including an organic insulating material; and a third encapsulation layer covering the second encapsulation layer, and including an inorganic insulating material. The second encapsulation layer may be spaced from the light transmitting area by the two or more light transmitting peripheral dams, the light transmitting hole may penetrate the second common layer and the second electrode, and in a portion of the light transmitting peripheral area between the two or more light transmitting peripheral dams and the light transmitting area, the third encapsulation layer may be in contact with the first encapsulation layer.

In an embodiment, the circuit layer may include: a first semiconductor layer on the support substrate; a first gate insulating layer covering the first semiconductor layer; a first gate conductive layer on the first gate insulating layer; a second gate insulating layer covering the first gate conductive layer; a second gate conductive layer on the second gate insulating layer; a first interlayer insulating layer covering the second gate conductive layer; a first source-drain conductive layer on the first interlayer insulating layer; a first planarization layer covering the first source-drain conductive layer; a second source-drain conductive layer on the first planarization layer; and a second planarization layer covering the second source-drain conductive layer. Each of the first gate insulating layer, the second gate insulating layer, and the interlayer insulating layer may include an inorganic insulating material. Each of the normal data lines, the first divided data lines of the intersecting data lines, and the second divided data lines of the intersecting data lines may be located in the second source-drain conductive layer, and each of the bypass data lines may be located in one of the first gate conductive layer or the second gate conductive layer.

In an embodiment, the shield line may be located in the first source-drain conductive layer.

In an embodiment, a portion of the first planarization layer overlapping with the display area may have a first thickness range, and another portion of the first planarization layer overlapping with the light transmitting peripheral area may have a second thickness range smaller than the first thickness range. The first planarization layer having the second thickness range may cover the shield line, and the two or more light transmitting peripheral dams may be located on the first planarization layer having the second thickness range.

In an embodiment, the circuit layer may further include an inorganic auxiliary insulating layer between the first source-drain conductive layer and the first planarization layer, and including an inorganic insulating material. The first encapsulation layer may be in contact with the inorganic auxiliary insulating layer through bonding grooves penetrating the second common layer and the second electrode. The bonding grooves may be located in a separation area between the two or more light transmitting peripheral dams, and on opposite sides of the two or more light transmitting peripheral dams.

In an embodiment, the circuit layer may further include: a second semiconductor layer on the first interlayer insulating layer; a third gate insulating layer covering the second semiconductor layer; a third gate conductive layer on the third gate insulating layer; and a second interlayer insulating layer covering the third gate conductive layer. The first source-drain conductive layer and the first planarization layer may be located on the second interlayer insulating layer, and each of the third gate insulating layer and the second interlayer insulating layer may include an inorganic insulating material. The shield line may be located in the third gate conductive layer, the first encapsulation layer may be in contact with the second interlayer insulating layer through bonding grooves penetrating the second common layer and the second electrode, and the bonding grooves may be located in a separation area between the two or more light transmitting peripheral dams, and on opposite sides of the two or more light transmitting peripheral dams.

In an embodiment, the shield line may include: a first shield layer located in the third gate conductive layer; and at least one second shield layer located in the first source-drain conductive layer, and electrically connected to the first shield layer. The two or more light transmitting peripheral dams may cover the at least one second shield layer.

In an embodiment, the circuit layer may further include bonding auxiliary layers located in the separation area between the two or more light transmitting peripheral dams, and on the opposite sides of the two or more light transmitting peripheral dams. The bonding auxiliary layers may be located on the second interlayer insulating layer of the light transmitting peripheral area, the bonding grooves may overlap with the bonding auxiliary layers, and the first encapsulation layer may be in contact with the bonding auxiliary layers through the bonding grooves.

In an embodiment, the circuit layer may further include: a second semiconductor layer on the first interlayer insulating layer; a third gate insulating layer covering the second semiconductor layer; a third gate conductive layer on the third gate insulating layer; a second interlayer insulating layer covering the third gate conductive layer; and bonding auxiliary layers located in a separation area between the two or more light transmitting peripheral dams, and on opposite sides of the two or more light transmitting peripheral dams. The first source-drain conductive layer and the first planarization layer may be located on the second interlayer insulating layer. Each of the third gate insulating layer and the second interlayer insulating layer may include an inorganic insulating material. The shield line may be located in the third gate conductive layer. Each of the bonding auxiliary layers may have an undercut structure including a main layer on the second interlayer insulating layer of the light transmitting peripheral area, and a roof layer on the main layer and protruding beyond the main layer. The first encapsulation layer may be in contact with a portion of a side surface of the main layer adjacent to the roof layer in each of the two or more bonding auxiliary layers.

In an embodiment, the first encapsulation layer and the third encapsulation layer may extend to at least a part of the light transmitting area, the third encapsulation layer may be in contact with the first encapsulation layer in at least a part of the light transmitting area, and the first encapsulation layer may be in contact with the support substrate through the light transmitting hole.

In an embodiment, the light transmitting hole may include: a first hole penetrating the second common layer and the second electrode; and a second hole penetrating the first encapsulation layer and the third encapsulation layer. The filling layer may be in contact with the support substrate through the light transmitting hole.

In an embodiment, the filling layer may include: a first filling portion overlapping with the display area and the light transmitting peripheral area, and including a first transparent material; and a second filling portion overlapping with the light transmitting area, and including a second transparent material having a higher refractive index than that of the first transparent material.

In an embodiment, the display device may further include a light blocking bank located between the first substrate and the second substrate, surrounding around the light transmitting area, and overlapping with the two or more light transmitting peripheral dams. The light blocking bank may include at least one of a light blocking material to block light, a light absorbing material to absorb light, or a transparent material having a higher refractive index than that of the filling layer.

According to one or more embodiments of the present disclosure, an electronic device includes: a display device configured to display an image; a memory configured to store an application; a processor configured to execute the application, and transmit an image data signal and an input control signal to the display device; and a power module configured to transmit power to the display device. The display device includes: a first substrate; a second substrate facing and bonded to the first substrate, each of the first substrate and the second substrate including: a display area including emission areas; a non-display area around the display area; a light transmitting area surrounded around by the display area; and a light transmitting peripheral area between the light transmitting area and the display area; and a filling layer filled between the first substrate and the second substrate. The first substrate further includes: a support substrate; a circuit layer on the support substrate; and two or more light transmitting peripheral dams in the light transmitting peripheral area, and spaced from each other. The circuit layer includes: light emitting pixel drivers along a first direction and a second direction in the display area; data lines extending in the second direction, and configured to transmit data signals to the light emitting pixel drivers; and a shield line in the light emitting peripheral area, and configured to transmit a constant voltage. The data lines include: intersecting data lines; and normal data lines spaced from the light transmitting area and the light transmitting peripheral area in the first direction. Each of the intersecting data lines includes: a bypass data line overlapping with the light emitting peripheral area; a first divided data line facing one side of the light transmitting peripheral area in the second direction; and a second divided data line facing another side of the light transmitting peripheral area in the second direction, and electrically connected to the first divided data line through the bypass data line. The shield line overlaps with the bypass data lines of the intersecting data lines in a third direction, and the two or more light transmitting peripheral dams overlap with the shield line in the third direction.

In an embodiment, the circuit layer may further include: a first semiconductor layer on the support substrate; a first gate insulating layer covering the first semiconductor layer; a first gate conductive layer on the first gate insulating layer; a second gate insulating layer covering the first gate conductive layer; a second gate conductive layer on the second gate insulating layer; a first interlayer insulating layer covering the second gate conductive layer; a first source-drain conductive layer on the first interlayer insulating layer; a first planarization layer covering the first source-drain conductive layer; a second source-drain conductive layer on the first planarization layer; and a second planarization layer covering the second source-drain conductive layer. Each of the first gate insulating layer, the second gate insulating layer, and the interlayer insulating layer may include an inorganic insulating material. Each of the normal data lines, the first divided data lines of the intersecting data lines, and the second divided data lines of the intersecting data lines may be located in the second source-drain conductive layer. Each of the bypass data lines may be located in one of the first gate conductive layer or the second gate conductive layer.

In an embodiment, the first substrate may further include: an element layer on the circuit layer; an encapsulation layer covering the element layer; and a light transmitting hole overlapping with the light transmitting area. The element layer may include: first electrodes in the emission areas, and electrically connected to the light emitting pixel drivers, respectively; a pixel defining layer in a non-emission area between the emission areas of the display area, and covering edges of the first electrodes; first common layers on the first electrodes; light emitting layers on the first common layers; a second common layer on the pixel defining layer and the light emitting layers; and a second electrode on the second common layer. The encapsulation layer may include: a first encapsulation layer on the element layer, and including an inorganic insulating material; a second encapsulation layer on the first encapsulation layer, and including an organic insulating material; and a third encapsulation layer covering the second encapsulation layer, and including an inorganic insulating material. The second encapsulation layer may be spaced from the light transmitting area by the two or more light transmitting peripheral dams, the light transmitting hole may penetrate the second common layer and the second electrode, and in a portion of the light transmitting peripheral area between the two or more light transmitting peripheral dams and the light transmitting area, the third encapsulation layer may be in contact with the first encapsulation layer.

In an embodiment, the circuit layer may further include an inorganic auxiliary insulating layer between the first source-drain conductive layer and the first planarization layer, and including an inorganic insulating material. The shield line may be located in the first source-drain conductive layer, the first encapsulation layer may be in contact with the inorganic auxiliary insulating layer through bonding grooves penetrating the second common layer and the second electrode, and the bonding grooves may be located in a separation area between the two or more light transmitting peripheral dams, and on opposite sides of the two or more light transmitting peripheral dams.

In an embodiment, the circuit layer may further include: a second semiconductor layer on the first interlayer insulating layer; a third gate insulating layer covering the second semiconductor layer; a third gate conductive layer on the third gate insulating layer; and a second interlayer insulating layer covering the third gate conductive layer. The first source-drain conductive layer and the first planarization layer may be on the second interlayer insulating layer, each of the third gate insulating layer and the second interlayer insulating layer may include an inorganic insulating material, and the shield line may be located in the third gate conductive layer. The first encapsulation layer may be in contact with the second interlayer insulating layer through bonding grooves penetrating the second common layer and the second electrode, and the bonding grooves may be located in a separation area between the two or more light transmitting peripheral dams, and on opposite sides of the two or more light transmitting peripheral dams.

According to some embodiments of the present disclosure, a display device may include a first substrate and a second substrate that face each other and are bonded together. Accordingly, each of the first substrate and the second substrate may have a strength sufficient for a bonding process, so that the strength of the display device may be improved, thereby preventing or substantially preventing the display device from being damaged (e.g., from being easily damaged).

According to some embodiments of the present disclosure, each of the first substrate and the second substrate may include a display area from which light is emitted, a non-display area located around the display area, a light transmitting area surrounded (e.g., around a periphery thereof) by the display area, and a light transmitting peripheral area located between the display area and the light transmitting area.

According to some embodiments of the present disclosure, the first substrate may include a support substrate, a circuit layer located on the support substrate, and two or more light transmitting peripheral dams located in the light transmitting peripheral area. The two or more light transmitting peripheral dams may have a ring shape surrounding (e.g., around a periphery of) the light transmitting area, and may be spaced apart from each other.

According to some embodiments of the present disclosure, the circuit layer may include light emitting pixel drivers arranged along a first direction and a second direction in the display area, data lines extending in the second direction and for transmitting data signals to the light emitting pixel drivers, and a shield line located in the light emitting peripheral area and for transmitting a constant voltage.

According to some embodiments of the present disclosure, the shield line may overlap with a part of each of the intersecting data lines that cross or intersect the light transmitting area and the light transmitting peripheral area among the data lines in a third direction.

According to some embodiments of the present disclosure, a portion of each of the intersecting data lines that crosses or intersects the light transmitting area and the light transmitting peripheral area may overlap with the shield line located in the light transmitting peripheral area, so that a coupling defect between the intersecting data lines that are arranged adjacent to each other in the light transmitting peripheral area may be reduced.

In other words, due to the shield line, a distortion of data signals of the intersecting data lines may be reduced.

Accordingly, although the display device and the electronic device including the display device according to some embodiments may include the light transmitting area for transmitting light to the optical device located under the display device, a deterioration of a display quality due to the light transmitting area may be prevented or reduced.

According to some embodiments of the present disclosure, two or more light transmitting peripheral dams may overlap with the shield line in the third direction.

In other words, two or more light transmitting peripheral dams may overlap with a part of each of the shield line and the intersecting data lines in the third direction.

Accordingly, a width of the light transmitting peripheral area may be reduced, so that a deterioration of a display quality due to the light transmitting area and the light transmitting peripheral area may be further prevented or reduced.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a perspective view showing an electronic device according to an embodiment;

FIG. 2 is an exploded perspective view showing the electronic device of FIG. 1 according to an embodiment;

FIG. 3 is a perspective view illustrating a display device of FIG. 2 according to an embodiment;

FIG. 4 is a plan view illustrating the display device of FIG. 3;

FIG. 5 is a cross-sectional view taken along the line A-A' of FIG. 4 according to an embodiment;

FIG. 6 is a schematic diagram showing an enlarged view of the part B of FIG. 4 according to an embodiment;

FIG. 7 is a block diagram illustrating the display device of FIG. 3 according to an embodiment;

FIG. 8 is an equivalent circuit diagram showing a light emitting pixel driver of FIG. 7 according to an embodiment;

FIG. 9 is a cross-sectional view taken along the line D-D' of FIG. 6 according to an embodiment;

FIG. 10 is a schematic diagram showing an enlarged view of the part C of FIG. 4 according to an embodiment;

FIG. 11 is a cross-sectional view taken along the line E-E’ of FIG. 10 according to an embodiment;

FIGS. 12 and 13 are cross-sectional views taken along the line F-F' of FIG. 10 according to some embodiments;

FIG. 14 is an equivalent circuit diagram showing a light emitting pixel driver of FIG. 7 according to an embodiment;

FIG. 15 is a cross-sectional view showing the light emitting pixel driver and a light emitting element of FIG. 14 according to an embodiment;

FIGS. 16 to 22 are cross-sectional views taken along the line F-F' of FIG. 10 according to some embodiments;

FIG. 23 is a block diagram of an electronic device according to an embodiment; and

FIG. 24 is schematic views of some electronic devices according to some embodiments.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

As used herein, the phrase "in a plan view" may refer to a view of an object portion from above, and the phrases "in a schematic cross-sectional view" and "in a cross-sectional view" may refer to a view of a schematic cross-section taken by vertically cutting an object portion from the side. The terms "overlap" or "overlapped" may refer to a first object overlapping with a second object from above, below, or to a side, and vice versa. Additionally, the term "overlap" may include a layer, a stack, a face or facing, extending over, covering, or partly covering, or any other suitable term as would be appreciated and understood by those having ordinary skill in the art. The expression "not overlap" may include meanings such as "apart from" or "set aside from" or "offset from" and any other suitable equivalents as would be appreciated and understood by those having ordinary skill in the art. The terms "face" and "facing" may mean that a first object may directly or indirectly oppose a second object. In a case in which a third object intervenes between a first and second object, the first and second objects may be understood as being indirectly opposed to one another, although still facing each other.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being "electrically connected" to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” "includes," "including," "has," "have," and "having," when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression "A and/or B" denotes A, B, or A and B. Expressions such as “at least one of,” when preceding a list of elements, modify the entire list of elements and do not modify the individual elements of the list. For example, the expression "at least one of a, b, or c," “at least one of a, b, and c,” and “at least one selected from the group consisting of a, b, and c” indicates only a, only b, only c, both a and b, both a and c, both b and c, all of a, b, and c, or variations thereof.

As used herein, the term "substantially," "about," and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms "use," "using," and "used" may be considered synonymous with the terms "utilize," "utilizing," and "utilized," respectively.

The electronic or electric devices and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

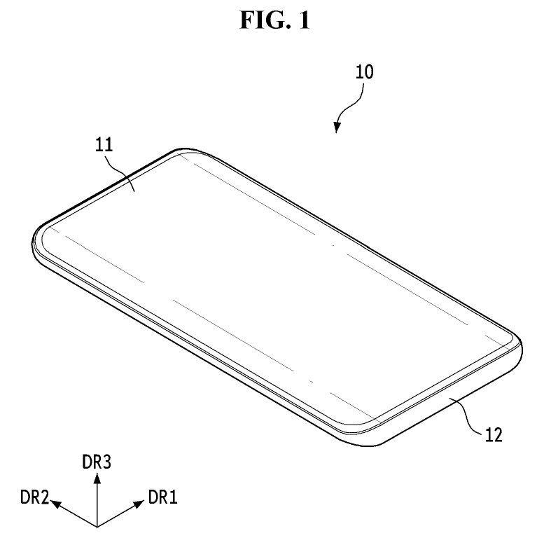

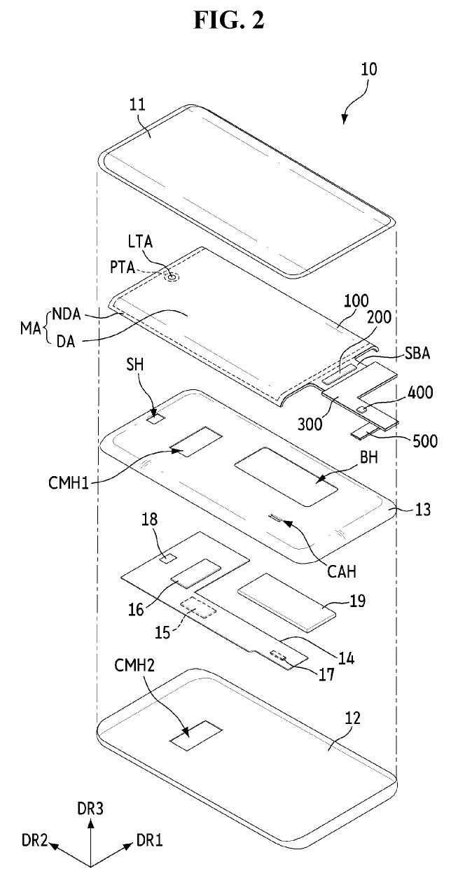

FIG. 1 is a perspective view showing an electronic device according to an embodiment. FIG. 2 is an exploded perspective view showing the electronic device of FIG. 1 according to an embodiment.

Referring to FIG. 1, an electronic device 10 according to an embodiment may be a device for displaying an image in a display area. The electronic device 10 may provide a portability. For example, the electronic device 10 may be a portable electronic device, such as a mobile phone, a smartphone, a tablet personal computer (PC), a smart watch, a watch phone, a mobile communication terminal, an electronic notebook, an electronic book, a portable multimedia player (PMP), a navigation device, and an ultra-mobile PC (UMPC).

However, the electronic device 10 is not limited to a portable electronic device, and may be a large-sized device, such as a television, a laptop computer, a monitor, a billboard, and an Internet-of-Things (IoT) device.

The electronic device 10 according to an embodiment may include a cover window 11 and a lower cover 12, which are provided as a housing to protect a display device 100 (e.g., see FIG. 2).

Referring to FIG. 2, the electronic device 10 may further include the display device 100, a bracket 13, and a main circuit board 14, which are accommodated between the cover window 11 and the lower cover 12.

The display device 100 may include a display area DA from which light is emitted for an image display, and a non-display area NDA located around the display area DA. The display device 100 may further include a light transmitting area LTA surrounded (e.g., around a periphery thereof) by the display area DA, and a light transmitting peripheral area PTA located between the display area DA and the light transmitting area LTA.

A region including the display area DA, the light transmitting area LTA, the light transmitting peripheral area PTA, and the non-display area NDA may be referred to as a main region MA.

The shape of the main region MA in a plan view may correspond to the shape of the electronic device 10 in a plan view.

The display area DA may be located in most of the main region MA. The display area DA may be located at the center of the main region MA.

The display device 100 may further include a sub-region SBA protruding from at least a portion of one edge of the main region MA.

The display device 100 may further include a display driving circuit 200 located in the sub-region SBA, a display circuit board 300 connected and bonded to pads located on one side of the sub-region SBA, a touch driving circuit 400 mounted on the display circuit board 300, and a cable 500 extending from one side of the display circuit board 300.

In the drawings, a first direction DR1 may be a direction parallel to or substantially parallel to a short side of the electronic device 10 in a plan view, or in other words, a horizontal direction of the electronic device 10. A second direction DR2 may be a direction parallel to or substantially parallel to a long side of the electronic device 10 in a plan view, or in other words, a vertical direction of the electronic device 10. A third direction DR3 may be a thickness direction of the electronic device 10.

The electronic device 10 may have a shape similar to (e.g., close to) a rectangular shape in a plan view. For example, the electronic device 10 may have a rectangular shape having a short side extending in the first direction DR1 and a long side extending in the second direction DR2 in a plan view. A corner where the short side extending in the first direction DR1 and the long side extending in the second direction DR2 meet each other may be right-angled, or may be rounded with a curvature (e.g., a selected or predetermined curvature). The shape of the electronic device 10 in a plan view is not limited to the rectangular shape, and may be one of a polygonal shape, a circular shape, or an elliptical shape, or a shape formed by a combination of two or more thereof.

The cover window 11 may be located on the display device 100 to cover the top surface of the display device 100. The cover window 11 may serve to protect the top surface of the display device 100.

The cover window 11 may include a light transmitting portion that is transparent, and a light blocking portion that is opaque.

The light transmitting portion may overlap with the display area DA of the display device 100 in the third direction DR3, and the light blocking portion may overlap with the non-display area NDA of the display device 100 in the third direction DR3.

The cover window 11 may include a top surface portion forming the top surface of the electronic device 10, a left surface portion forming the left side surface of the electronic device 10, and a right surface portion forming the right side surface of the electronic device 10. The left surface portion of the cover window 11 may extend from the left side of the top surface portion, and the right surface portion of the cover window 11 may extend from the right side of the top surface portion.

Each of the top, left, and right surface portions of the cover window 11 may include the light transmitting portion and the light blocking portion.

The light transmitting portion of the cover window 11 may be located on most of each of the top, left, and right surface portions of the cover window 11.

The light blocking portion of the cover window 11 may be located at the upper edge and lower edge of the top surface portion of the cover window 11, the upper edge, left edge, and lower edge of the left surface portion of the cover window 11, and the upper edge, right edge, and lower edge of the right surface portion of the cover window 11.

The display device 100 may be located below the cover window 11.

In other words, the cover window 11 may be located on the display device 100.

The display device 100 may include a top surface portion facing the top surface portion of the cover window 11, a left surface portion facing the left surface portion of the cover window 11, and a right surface portion facing the right surface portion of the cover window 11. The left surface portion of the display device 100 may extend from the left side of the top surface portion, and the right surface portion of the display device 100 may extend from the right side of the top surface portion.

In other words, each of the top, left, and right surface portions of the display device 100 may include the display area DA and the non-display area NDA.

The display area DA may be located on most of each of the top, left, and right surface portions of the display device 100.

The non-display area NDA may be located outside the display area DA. The non-display area NDA may be an edge area of the main region MA.

The non-display area NDA may be located at the upper edge and lower edge of the top surface portion of the display device 100, the upper edge, left edge, and lower edge of the left surface portion of the display device 100, and the upper edge, right edge, and lower edge of the right surface portion of the display device 100.

The sub-region SBA may protrude from at least a part of one side of the main region MA in the second direction DR2.

The length of the sub-region SBA in the first direction DR1 may be less than or equal to the length of the main region MA in the first direction DR1. The length of the sub-region SBA in the second direction DR2 may be less than the length of the main region MA in the second direction DR2, but the present disclosure is not limited thereto.

Because a part of the sub-region SBA may be bent, another part of the sub-region SBA may overlap with the main region MA in the third direction DR3.

The display driving circuit 200 may be mounted on the sub-region SBA, and the display circuit board 300 may be attached to the sub-region SBA.

One end of the display circuit board 300 may be attached to pads located at the lower edge of the sub-region SBA of the display device 100 by using an anisotropic conductive film.

The display circuit board 300 may be a flexible printed circuit board (FPCB) that is bendable, a rigid printed circuit board (PCB) that maintains a flat or substantially flat shape, or a composite printed circuit board having both of the rigid printed circuit board and the flexible printed circuit board.

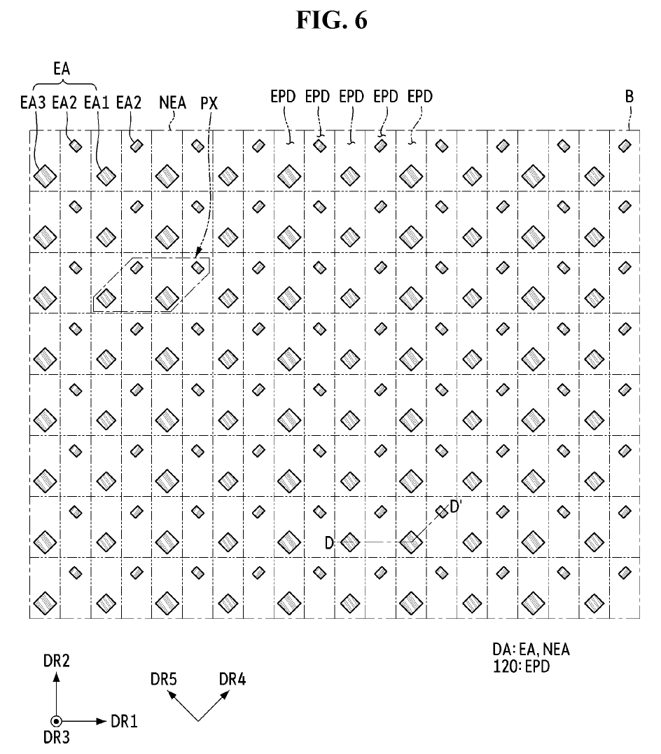

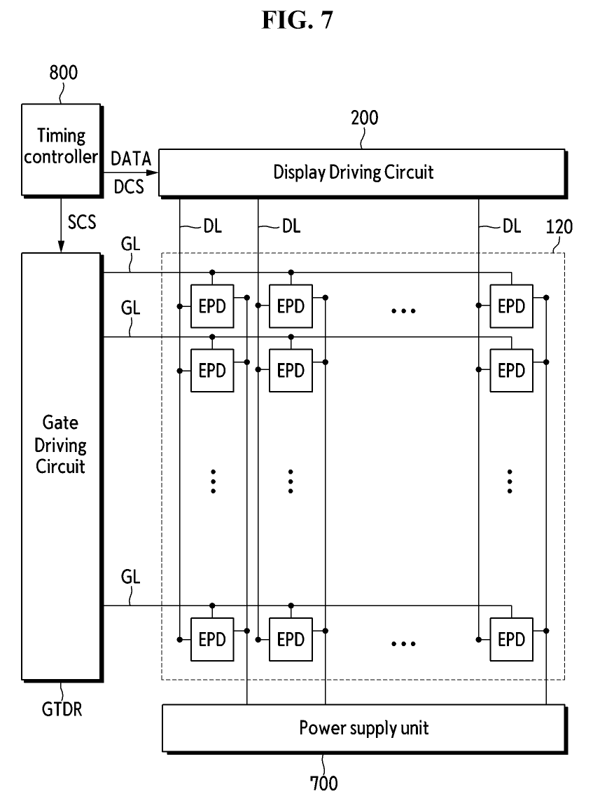

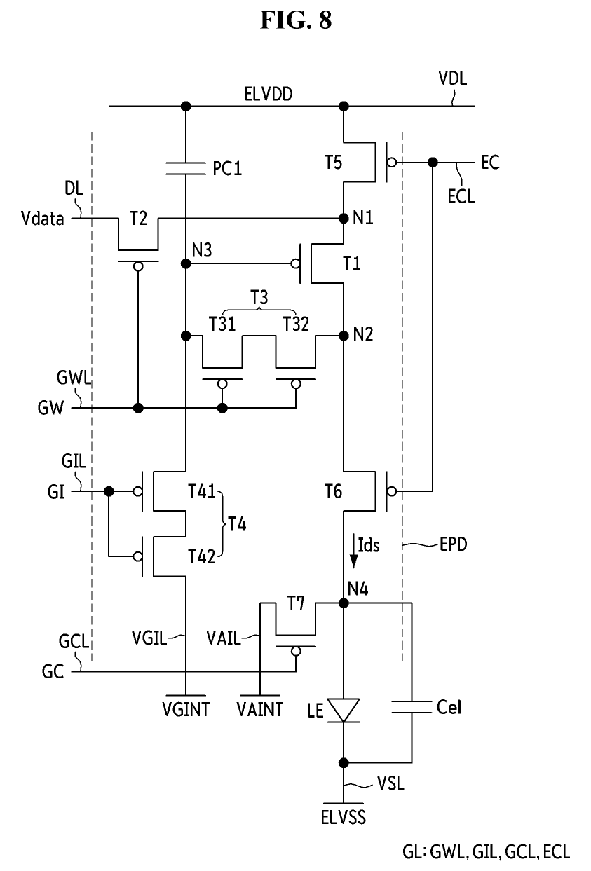

Based on control signals, power, and voltages supplied through the display circuit board 300, the display driving circuit 200 may transmit data signals Vdata (e.g., see FIG. 8) of light emitting pixel drivers EPD (e.g., see FIG. 6) of the display area DA to data lines DL (e.g., see FIG. 7).

The display driving circuit 200 may be provided as an integrated circuit (IC), and mounted on the sub-region SBA of the display device 100 by a chip on glass (COG) method, a chip on plastic (COP) method, or an ultrasonic method. However, the present disclosure is not limited thereto. For example, the display driving circuit 200 may be mounted on the display circuit board 300.

According to an embodiment, the touch driving circuit 400 may be further mounted on the sub-region SBA of the display device 100.

In another embodiment, as shown in FIG. 2, the touch driving circuit 400 may be mounted on the display circuit board 300.

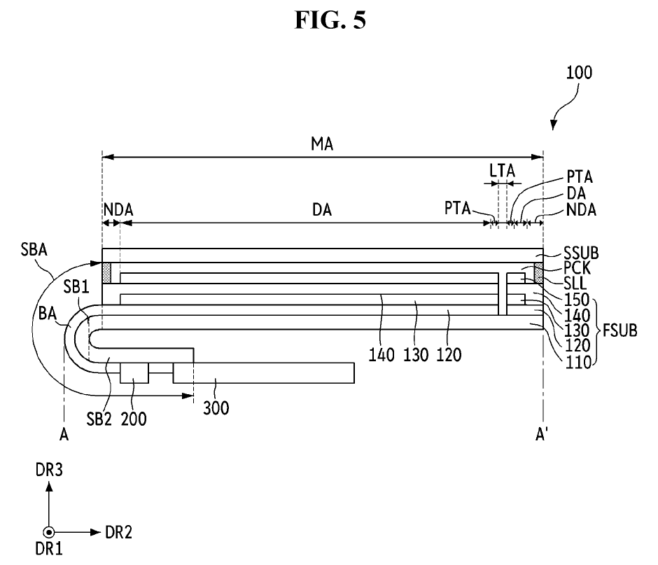

The touch driving circuit 400 may be electrically connected to a touch sensor layer 150 (e.g., see FIG. 5) of the display device 100.

As shown in FIG. 2, the bracket 13 may be located under the display device 100.

The bracket 13 may include a plastic or a metal. The bracket 13 may include a first camera hole CMH1 into which a camera device 16 is inserted, a battery hole BH in which a battery 19 is located, an optical device hole SH into which an optical device 18 is inserted, and a cable hole CAH through which the cable 500 connected to the display circuit board 300 passes.

The main circuit board 14 and the battery 19 may be located under the bracket 13.

The main circuit board 14 may be a printed circuit board or a flexible printed circuit board.

A main processor 15, the camera device 16, a main connector 17, and the optical device 18 may be mounted on the main circuit board 14.

The camera device 16 may be located on both the top surface and the bottom surface of the main circuit board 14.

The main processor 15 may be located on the top surface of the main circuit board 14.

The main connector 17 may be located on the bottom surface of the main circuit board 14.

The main processor 15 may be formed as an integrated circuit, and control all functions of the electronic device 10.

For example, the main processor 15 may output digital video data to the display driving circuit 200 through the display circuit board 300, such that the display device 100 displays an image. In addition, the main processor 15 may receive touch data including user's touch coordinates from the touch driving circuit 400, determine whether or not the user has touched or approached, and then perform an operation corresponding to the user's touch input or approach input. For example, the main processor 15 may perform an operation, or may execute an application indicated by an icon touched by the user.

The main processor 15 may be an application processor formed as an integrated circuit, a central processing unit, or a system chip.

The camera device 16 may process an image frame of a still image or a video obtained by an image sensor in a camera mode, and may output it to the main processor 15.

The cable 500 may pass through the cable hole CAH of the bracket 13 to be connected to the main connector 17. Thus, the main circuit board 14 may be electrically connected to the display circuit board 300.

The optical device 18 may include at least one of a proximity sensor, an illuminance sensor, an iris sensor, or an additional (e.g., a second) camera sensor.

The proximity sensor, the illumination sensor, the iris sensor, and the second camera sensor may be located on the top surface of the main circuit board 14 and in the optical device hole SH of the bracket 13.

The proximity sensor is a sensor for detecting an object approaching the front surface of the electronic device 10. The proximity sensor may include a light source that outputs light, and a light receiver that receives light reflected by an object. The proximity sensor may generate a sensing signal corresponding to the amount of light reflected by the object, and a presence or an absence of an object near the front surface of the electronic device 10 may be determined based on the sensing signal of the proximity sensor.

The illuminance sensor is a sensor for detecting the brightness of the front surface of the electronic device 10. The illuminance sensor may include a resistor having a resistance value that changes according to the brightness of the incident light.

The iris sensor is a sensor for imaging the user's iris. It may be verified whether or not the user is a pre-registered user based on whether or not the image captured by the iris sensor is the same as an iris image previously stored in a memory.

The additional camera sensor may process an image frame of a still image or a video obtained by the image sensor, and may output it to the main processor 15. The additional camera sensor may be a complementary metal–oxide–semiconductor (CMOS) image sensor or a charge-coupled device (CCD) sensor. The number of pixels of the additional camera sensor may be smaller than the number of pixels of the camera device 16, and the size of the additional camera sensor may be smaller than the size of the camera device 16.

The battery 19 may be located so as not to overlap with the main circuit board 14 in the third direction DR3. The battery 19 may overlap with the battery hole BH of the bracket 13 in the third direction DR3.

In addition, the main circuit board 14 may be further equipped with a mobile communication module capable of transmitting and receiving radio signals with at least one of a base station, an external terminal, or a server in a mobile communication network. The radio signal may include various suitable kinds of data according to a transmission and a reception of a voice signal, a video call signal, or a text/multimedia message.

The lower cover 12 may be located below the main circuit board 14 and the battery 19. The lower cover 12 may be fixed by being fastened to the bracket 13. The lower cover 12 may form the upper side surface, lower side surface, and bottom surface of the electronic device 10. The lower cover 12 may include a plastic, a metal, or both a plastic and a metal.

The lower cover 12 may include a second camera hole CMH2 through which the bottom surface of the camera device 16 is exposed.

The position of the camera device 16 in the main region MA, the position of the first camera hole CMH1 in the bracket 13 corresponding to the camera device 16, and the position of the second camera hole CMH2 in the lower cover 12 corresponding to the camera device 16 are not limited to those illustrated into those illustrated in FIG. 2.

In addition, the position of the optical device 18 in the main region MA and the position of the optical device hole SH in the bracket 13 are not limited to those illustrated into those illustrated in FIG. 2.

The display device 100 according to some embodiments will be described in more detail hereinafter.

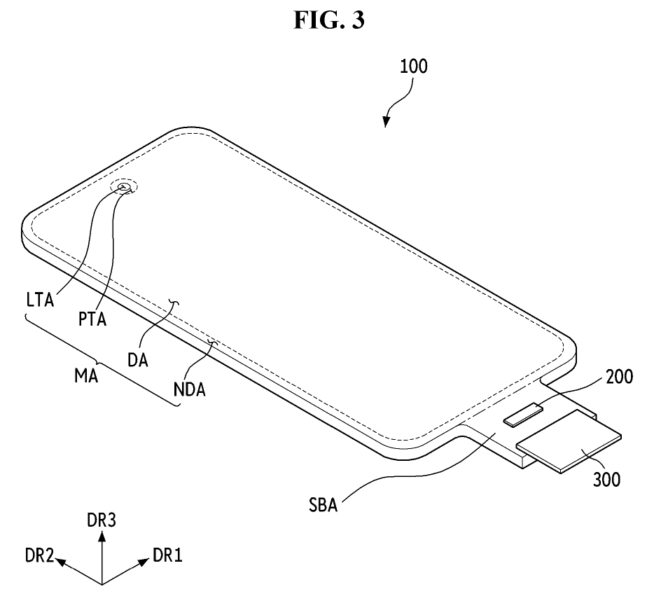

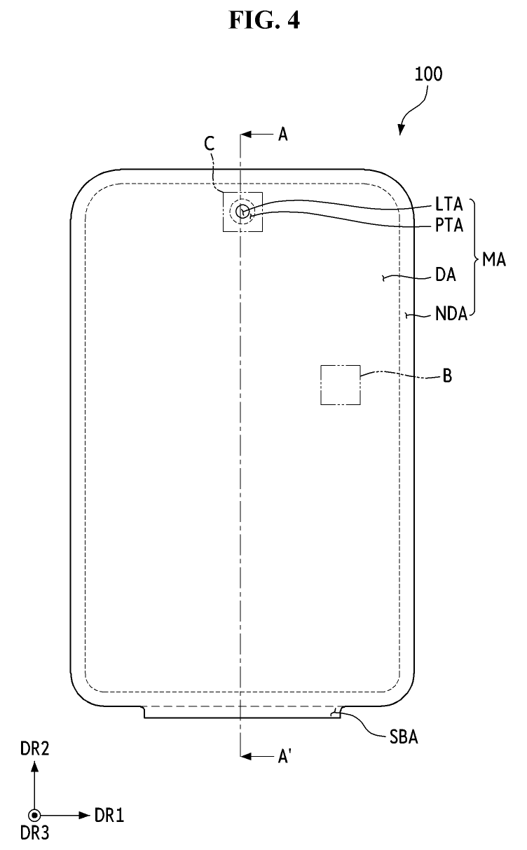

FIG. 3 is a perspective view illustrating the display device of FIG. 2 according to an embodiment. FIG. 4 is a plan view illustrating the display device of FIG. 3. FIG. 5 is a cross-sectional view taken along the line A-A' of FIG. 4 according to an embodiment.

Referring to FIGS. 3 and 4, the display device 100 according to an embodiment may be a device for displaying a moving image or a still image. The display device 100 may be used as a display screen of various suitable devices, such as a television, a laptop computer, a monitor, a billboard, and an Internet-of-Things (IOT) device, as well as for various suitable portable electronic devices, such as a mobile phone, a smartphone, a tablet personal computer (PC), a smart watch, a watch phone, a mobile communication terminal, an electronic notebook, an electronic book, a portable multimedia player (PMP), a navigation device, and an ultra-mobile PC (UMPC).

The display device 100 may be a light emitting display device, such as an organic light emitting display using an organic light emitting diode, a quantum dot light emitting display including a quantum dot light emitting layer, an inorganic light emitting display including an inorganic semiconductor, and a micro light emitting display using a micro or nano light emitting diode (LED). Hereinafter, for convenience of illustration, the display device 100 may be described in more detail in the context of an organic light emitting display device. However, the present disclosure is not limited thereto, and the display device may be any suitable kind of display device, such as a display device including an organic insulating material, an organic light emitting material, and a metal material.

The display device 100 may be formed to be flat or substantially flat, but is not limited thereto. For example, the display device 100 may include a curved portion formed at left and right ends, and having a constant curvature or a varying curvature. In addition, the display device 100 may be formed to be flexible so that it may be curved, bent, folded, or rolled.

Referring to FIG. 3, at least one surface of the display device 100 may be a display surface that emits light for displaying an image.

The display surface of the display device 100 may include the main region MA.

The main region MA may include the display area DA from which light is emitted for an image display, the non-display area NDA located around the display area DA, the light transmitting area LTA surrounded (e.g., around a periphery thereof) by the display area DA, and the light transmitting peripheral area PTA located between the display area DA and the light transmitting area LTA.

In a plan view, the main region MA may be formed in a rectangular shape having short sides extending in the first direction DR1, and long sides extending in the second direction DR2 crossing the first direction DR1. A corner where a short side extending in the first direction DR1 and a long side extending in the second direction DR2 meet each other may be rounded to have a suitable curvature (e.g., a selected or predetermined curvature), or may be right-angled. The planar shape of the main region MA is not limited to the rectangular shape, and may be formed in another polygonal shape, a circular shape, or an elliptical shape.

The display area DA may be located in most of the main region MA. The display area DA may be located at the center of the main region MA. The display area DA may have a shape similar to that of the main region MA.

The display device 100 may further include the sub-region SBA protruding in the second direction DR2 from at least a part of one side of the main region MA.

As shown in FIGS. 4 and 5, a part of the sub-region SBA is transformed (e.g., is bent) to be curved, so that another part of the sub-region SBA may be located on the rear surface of the display device 100.

As shown in FIG. 5, the display device 100 according to an embodiment may include a first substrate FSUB and a second substrate SSUB that face each other and are bonded together, and a filling layer PCK filled between the first substrate FSUB and the second substrate SSUB.

The display device 100 may further include a sealing layer SLL located in the non-display area NDA between the first substrate FSUB and the second substrate SSUB.

The first substrate FSUB and the second substrate SSUB may be bonded together by the sealing layer SLL.

The filling layer PCK may fill a space surrounded by the first substrate FSUB, the second substrate SSUB, and the sealing layer SLL, and may include a transparent organic material.

Each of the first substrate FSUB and the second substrate SSUB may include the main region MA. The main region MA may include the display area DA, the non-display area NDA, the light transmitting area LTA, and the light transmitting peripheral area PTA.

In other words, each of the first substrate FSUB and the second substrate SSUB may include the display area DA, the non-display area NDA, the light transmitting area LTA, and the light transmitting peripheral area PTA.

The first substrate FSUB may include a support substrate 110, a circuit layer 120 located on the support substrate 110, an element layer 130 located on the circuit layer 120, and an encapsulation layer 140 covering the element layer 130.

The first substrate FSUB may further include the touch sensor layer 150 located on the encapsulation layer 140.

At least one of the first substrate FSUB or the second substrate SSUB may include a polarizing layer for reducing a reflection of external light.

Each of the support substrate 110 and the second substrate SSUB may include at least one material selected from the group consisting of glass, a polymer material, and a plastic.

The second substrate SSUB may contain a transparent material.

Each of the support substrate 110 and the second substrate SSUB may have a strength sufficient to maintain its shape without being damaged under the pressure of a bonding process.

The circuit layer 120 may include at least one semiconductor layer, two or more conductive layers, and insulating layers respectively covering them. The circuit layer 120 may include the light emitting pixel drivers EPD (e.g., see FIG. 6) corresponding to emission areas EA, and each of the light emitting pixel drivers EPD may include two or more transistors electrically connected to wires for transmitting signals or voltages.

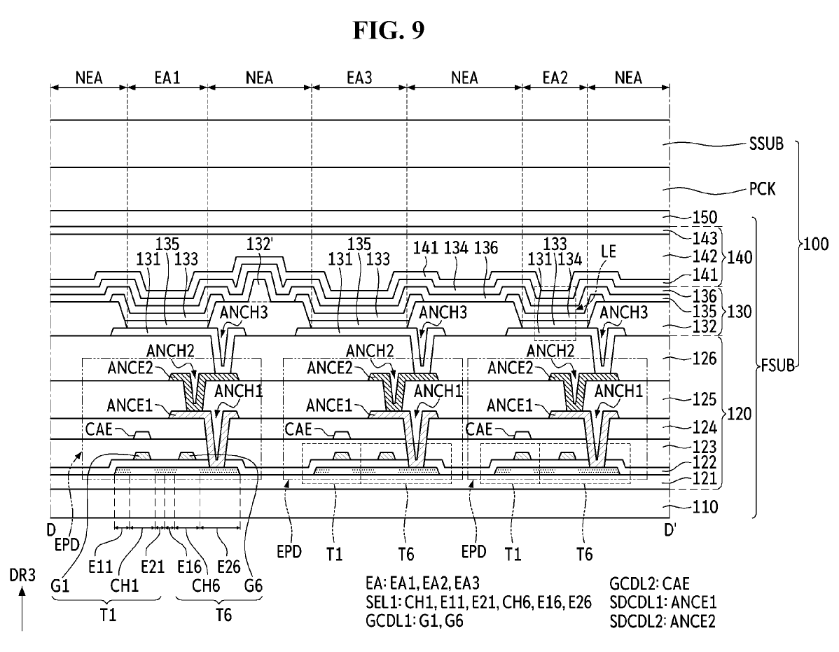

The element layer 130 may include light emitting elements LE (e.g., see FIGS. 8 and 9) located in the emission areas EA.

The encapsulation layer 140 may cover the element layer 130.

The encapsulation layer 140 may have a suitable structure including two or more inorganic insulating layers, and at least one organic layer interposed between the inorganic insulating layers.

Because an organic light emitting material of the light emitting elements LE of the element layer 130 may be sealed by the encapsulation layer 140, a degradation of the light emitting elements LE due to oxygen or moisture may be delayed, reduced, or prevented.

The sub-region SBA may include a bending area BA that is transformed (e.g., that is bent) into a bent shape, a first sub-region SB1 located between one side of the main region MA and the bending area BA, and a second sub-region SB2 connected to another side (e.g., an opposite side) of the bending area BA and overlapping with the main region MA in the third direction DR3.

The display driving circuit 200 may be mounted in the second sub-region SB2.

The display circuit board 300 may be bonded to the pads located in the second sub-region SB2, and may be electrically connected to the pads.

FIG. 6 is a schematic diagram showing and enlarged view of the part B of FIG. 4 according to an embodiment.

Referring to FIG. 6, the display area DA (e.g., see FIG. 3) may include emission areas EA that emit light, and a non-emission area NEA located between the emission areas EA.

The emission areas EA may include first emission areas EA1 for emitting light of a first color in a suitable wavelength band (e.g., a predetermined wavelength band), second emission areas EA2 for emitting light of a second color in a wavelength band lower than that of the first color, and third emission areas EA3 for emitting light of a third color in a wavelength band lower than that of the second color.

For example, the first color may be red having a wavelength band of approximately 600 nm to 750 nm. The second color may be green having a wavelength band of approximately 480 nm to 560 nm. The third color may be blue having a wavelength band of approximately 370 nm to 460 nm.

The first emission areas EA1 and the third emission areas EA3 may be alternately located in at least one of the first direction DR1 or the second direction DR2.

The second emission areas EA2 may be arranged side by side with each other in at least one of the first direction DR1 or the second direction DR2.

In addition, the second emission areas EA2 may be adjacent to the first emission areas EA1 and the third emission areas EA3 in diagonal directions DR4 and DR5 crossing the first direction DR1 and the second direction DR2.

Pixels PX for displaying their own luminances and colors may be provided by the first emission area EA1, the second emission area EA2, and the third emission area EA3 that are adjacent to each other among the emission areas EA.

In other words, the pixel PX may be a basic unit for displaying various desired colors including white having a desired luminance (e.g., a predetermined luminance).

Each of the pixels PX may include at least one first emission area EA1, at least one second emission area EA2, and at least one third emission area EA3 that are adjacent to each other. Accordingly, each of the pixels PX may display various desired colors through a mixture of the light emitted from the first emission area EA1, the second emission area EA2, and the third emission area EA3 that are adjacent to each other.

The arrangement of the first emission areas EA1, the second emission areas EA2, and the third emission areas EA3 is not limited to that illustrated in FIG. 6.

According to an embodiment, the element layer 130 (e.g., see FIG. 5) may include the light emitting elements LE (e.g., see FIGS. 8 and 9) respectively located in the emission areas EA.

The circuit layer 120 (e.g., see FIG. 5) may include the light emitting pixel drivers EPD electrically connected to the light emitting elements LE, respectively.

The light emitting pixel drivers EPD may be arranged in the first direction DR1 and the second direction DR2.

FIG. 7 is a block diagram illustrating the display device of FIG. 3 according to an embodiment.

Referring to FIG. 7, the circuit layer 120 of the display device 100 according to an embodiment may include the light emitting pixel drivers EPD electrically connected to the light emitting elements LE (e.g., see FIGS. 8 and 9) of the emission areas EA (e.g., see FIG. 6), respectively, gate lines GL for transmitting gate signals GS (e.g., see FIG. 8) to the light emitting pixel drivers EPD, and the data lines DL for transmitting the data signals Vdata to the light emitting pixel drivers EPD.

Each of the gate signals is used to control a turn-on/turn-off operation of at least one of two or more transistors provided in each of the light emitting pixel drivers EPD.

Each of data signals Vdata is used to control the luminance of the light emitting elements LE.

According to an embodiment, the display device 100 may further include a gate driver (e.g., a gate driving circuit) GTDR that outputs gate signals to the gate lines GL, a power supply unit (e.g., a power supply or a power supply circuit) 700 that supplies power and voltages to the light emitting pixel drivers EPD, and a timing controller 800 that controls the driving timing of each of the display driving circuit 200 and the gate driver GTDR.

The timing controller 800 receives an image signal supplied from the outside of the display device 100.

The timing controller 800 may output image data DATA and a data control signal DCS to the display driving circuit 200.

The timing controller 800 may generate a scan control signal SCS for controlling the operation timing of the gate driver GTDR.

The display driving circuit 200 may convert the image data DATA into analog data voltages according to the data control signal DCS, and may output the data signals Vdata to the data lines DL.

The gate driver GTDR may generate gate signals in response to the scan control signal SCS, and may sequentially output the gate signals to gate lines GL.

The gate signals may have pulses that vary to a first gate level voltage or a second gate level voltage.

The power supply unit 700 may supply various suitable power and voltages used for driving the light emitting pixel drivers EPD.

FIG. 8 is an equivalent circuit diagram showing a light emitting pixel driver of FIG. 7 according to an embodiment.

Referring to FIG. 8, the light emitting pixel driver EPD of the circuit layer 120 may be electrically connected to a first power line VDL for transmitting a first power ELVDD and the light emitting element LE of the element layer 130. The light emitting element LE of the element layer 130 may be electrically connected to a second power line VSL for transmitting a second power ELVSS.

The first power ELVDD may have a higher voltage level than that of the second power ELVSS.

In other words, the first electrode (e.g., an anode electrode) of the light emitting element LE may be electrically connected to the light emitting pixel driver EPD, and the second electrode (e.g., a cathode electrode) of the light emitting element LE may be electrically connected to the second power line VSL.

A capacitor Cel connected in parallel with the light emitting element LE refers to a parasitic capacitance between the first electrode and the second electrode.

According to an embodiment, the light emitting pixel driver EPD may include a first transistor T1 to generate a driving current Ids for driving the light emitting element LE, two or more transistors T2 to T7 electrically connected to the first transistor T1 or the light emitting element LE, and a first capacitor PC1.

The light emitting pixel driver EPD may be electrically connected to the gate lines GL for transmitting the gate signals, and to the data line DL for transmitting the data signal Vdata.

The gate signals may include a scan write signal GW for turn-on/turn-off operations of a second transistor T2 and a third transistor T3, a scan initialization signal GI for a turn-on/turn-off operation of a fourth transistor T4, an emission control signal EC for turn-on/turn-off operations of a fifth transistor T5 and a sixth transistor T6, and a gate control signal GC for a turn-on/turn-off operation of a seventh transistor T7.

In other words, the gate lines GL may include a scan write line GWL for transmitting the scan write signal GW, a scan initialization line GIL for transmitting the scan initialization signal GI, an emission control line ECL for transmitting the emission control signal EC, and a gate control line GCL for transmitting the gate control signal GC.

The light emitting pixel driver EPD may be electrically connected to a first initialization voltage line VGIL to transmit a first initialization voltage VGINT for initializing a potential of the gate electrode of the first transistor T1, and a second initialization voltage line VAIL to transmit a second initialization voltage VAINT for initializing a potential of the first electrode of the light emitting element LE.

The first transistor T1 may be electrically connected between a first node N1 and a second node N2.

The first node N1 may be electrically connected to the first electrode (e.g., a source electrode) of the first transistor T1.

The second node N2 may be electrically connected to the second electrode (e.g., a drain electrode) of the first transistor T1.

The gate electrode of the first transistor T1 may be electrically connected to a third node N3.

The second transistor T2 may be electrically connected between the data line DL and the first node N1.

The gate electrode of the second transistor T2 may be electrically connected to the scan write line GWL, and the second transistor T2 may be turned on by the scan write signal GW.

The first capacitor PC1 may be electrically connected between the third node N3 and the first power line VDL.

The potential of the gate electrode of the first transistor T1 may correspond to a voltage charged in the first capacitor PC1.

When the second transistor T2 is turned on, the data signal Vdata of the data line DL is transmitted to the first electrode of the first transistor T1, so that a voltage difference between the gate electrode of the first transistor T1 and the first electrode of the first transistor T1 may be a difference voltage between the first power ELVDD and the data signal Vdata.

In this case, when the voltage difference between the gate electrode of the first transistor T1 and the first electrode of the first transistor T1, or in other words, the gate-source voltage difference, becomes equal to or greater than a threshold voltage, the first transistor T1 is turned on, so that a drain-source current Ids of the first transistor T1 corresponding to the data signal Vdata may be generated.

The fifth transistor T5 may be electrically connected between the first node N1 and the first power line VDL.

The sixth transistor T6 may be electrically connected between the second node N2 and a fourth node N4.

The fourth node N4 may be electrically connected to the first electrode of the light emitting element LE.

The gate electrode of the fifth transistor T5 and the gate electrode of the sixth transistor T6 may be electrically connected to the emission control line ECL, and the fifth transistor T5 and the sixth transistor T6 may be turned on by the emission control signal EC.

When the fifth transistor T5 and the sixth transistor T6 are turned on, the first transistor T1 and the light emitting element LE may be connected in series between the first power source ELVDD and the second power source ELVSS. Accordingly, the drain-source current Ids of the first transistor T1 corresponding to the data signal Vdata may be transmitted as a driving current of the light emitting element LE.

Accordingly, the light emitting element LE may emit light having a luminance corresponding to the data signal Vdata.

The third transistor T3 may be electrically connected between the second node N2 and the third node N3.

In other words, the third transistor T3 may be electrically connected between the gate electrode of the first transistor T1 and the second electrode of the first transistor T1.

The third transistor T3 may include a plurality of sub-transistors connected in series. For example, the third transistor T3 may include a first sub-transistor T31 and a second sub-transistor T32.

The first electrode of the first sub-transistor T31 may be connected to the gate electrode of the first transistor T1, the second electrode of the first sub-transistor T31 may be connected to the first electrode of the second sub-transistor T32. The second electrode of the second sub-transistor T32 may be connected to the second electrode of the first transistor T1.

As such, it may be possible to prevent or substantially prevent the potential of the gate electrode of the first transistor T1 from changing due to a leakage current caused by the third transistor T3 that is not turned on.

The gate electrode of the first sub-transistor T31 and the gate electrode of the second sub-transistor T32 may be electrically connected to the scan write line GWL, and the first sub-transistor T31 and the second sub-transistor T32 may be turned on by the scan write signal GW.

When the first sub-transistor T31 and the second sub-transistor T32 are turned on, a voltage difference between the second node N2 and the third node N3 may be initialized.

The fourth transistor T4 may be electrically connected between the third node N3 and the first initialization voltage line VGIL. In other words, the fourth transistor T4 may be connected between the gate electrode of the first transistor T1 and the first initialization voltage line VGIL.

The fourth transistor T4 may include a plurality of sub-transistors connected in series. For example, the fourth transistor T4 may include a third sub-transistor T41 and a fourth sub-transistor T42.

The first electrode of the third sub-transistor T41 may be connected to the gate electrode of the first transistor T1, the second electrode of the third sub-transistor T41 may be connected to the first electrode of the fourth sub-transistor T42. The second electrode of the fourth sub-transistor T42 may be connected to the first initialization voltage line VGIL.

As such, it may be possible to prevent or substantially prevent the potential of the gate electrode of the first transistor T1 from changing due to a leakage current caused by the fourth transistor T4 that is not turned on.

The gate electrode of the third sub-transistor T41 and the gate electrode of the fourth sub-transistor T42 may be electrically connected to the scan initialization line GIL, and the third sub-transistor T41 and the fourth sub-transistor T42 may be turned on by the scan initialization signal GI.

When the third sub-transistor T41 and the fourth sub-transistor T42 are turned on, the potential of the third node N3 may be initialized to the first initialization voltage VGINT.

The seventh transistor T7 may be electrically connected between the fourth node N4 and the second initialization voltage line VAIL.

The gate electrode of the seventh transistor T7 may be electrically connected to the gate control line GCL, and the seventh transistor T7 may be turned on by the gate control signal GC.

When the seventh transistor T7 is turned on, the potential of the fourth node N4 and the first electrode of the light emitting element LE electrically connected to the fourth node N4 may be initialized to the second initialization voltage VAINT.

According to an embodiment, the first to seventh transistors T1 to T7 may be formed as P-type MOSFETs.

According to another embodiment, the first to seventh transistors T1 to T7 may be formed as N-type MOSFETs.

According to another embodiment, some of the first to seventh transistors T1 to T7 may be formed as N-type MOSFETs, and others thereof may be formed as P-type MOSFETs. As an example, the third transistor T3 and the fourth transistor T4 may be formed as N-type MOSFETs, and the first transistor T1, the second transistor T2, the fifth transistor T5, the sixth transistor T6, and the seventh transistor T7 may be formed as P-type MOSFETs.

FIG. 9 is a cross-sectional view taken along the line D-D' of FIG. 6 according to an embodiment.

FIG. 9 illustrates the first transistor T1, the sixth transistor T6, and the light emitting element LE.

Referring to FIG. 9, the display device 100 according to an embodiment may include the first substrate FSUB and the second substrate SSUB facing each other, and the filling layer PCK filled between the first substrate FSUB and the second substrate SSUB.

According to an embodiment, the first substrate FSUB may include the support substrate 110, and the circuit layer 120 located on the support substrate 110.

According to an embodiment, the first substrate FSUB may include the element layer 130 located on the circuit layer 120, and the encapsulation layer 140 covering the element layer 130.

The first substrate FSUB may further include the touch sensor layer 150 located on the encapsulation layer 140.

According to an embodiment, the circuit layer 120 may include a first semiconductor layer SEL1 located on the support substrate 110, a first gate insulating layer 122 covering the first semiconductor layer SEL1, a first gate conductive layer GCDL1 located on the first gate insulating layer 122, a second gate insulating layer 123 covering the first gate conductive layer GCDL1, a second gate conductive layer GCDL2 located on the second gate insulating layer 123, a first interlayer insulating layer 124 covering the second gate conductive layer GCDL2, a first source-drain conductive layer SDCDL1 located on the first interlayer insulating layer 124, a first planarization layer 125 covering the first source-drain conductive layer SDCDL1, a second source-drain conductive layer SDCDL2 located on the first planarization layer 125, and a second planarization layer 126 covering the second source-drain conductive layer SDCDL2.

The circuit layer 120 may further include the buffer layer 121 covering the support substrate 110. In this case, the first semiconductor layer SEL1 may be located on the buffer layer 121.

The first semiconductor layer SEL1 may include channel portions CH1 and CH6, first electrode portions E11 and E16, and second electrode portions E21 and E26 of the first and sixth transistors T1 and T6.

In addition, in an embodiment as illustrated in FIG. 8, when the second transistor T2, the third transistor T3, the fourth transistor T4, the fifth transistor T5, and the seventh transistor T7 are P-type MOSFETs, as is the case with the first transistor T1 and the sixth transistor T6, the first semiconductor layer SEL1 may further include channel portions, first electrode portions, and second electrode portions of the second transistor T2, the third transistor T3, the fourth transistor T4, the fifth transistor T5, and the seventh transistor T7.

The second electrode portion E21 of the first transistor T1 may be connected to the first electrode portion E16 of the sixth transistor T6.

The first gate conductive layer GCDL1 may include the gate electrodes G1 and G6 of the first transistor T1 and the sixth transistor T6, respectively.

The gate electrode G1 of the first transistor T1 may overlap with the channel portion CH1 of the first transistor T1 in the third direction DR3.

The gate electrode G6 of the sixth transistor T6 may overlap with the channel portion CH6 of the sixth transistor T6 in the third direction DR3.

The second gate conductive layer GCDL2 may include a capacitor electrode CAE.

The capacitor electrode CAE may overlap with the gate electrode G1 of the first transistor T1 in the third direction DR3.

The capacitor electrode CAE may be electrically connected to the first power line VDL (e.g., see FIG. 8).

Accordingly, the first capacitor PC1 may be formed by a region in which the capacitor electrode CAE and the gate electrode G1 of the first transistor T1 overlap with each other in the third direction DR3.

The first source-drain conductive layer SDCDL1 may include a first anode connection electrode ANCE1.

The first anode connection electrode ANCE1 may be electrically connected to the second electrode portion E26 of the sixth transistor T6 through a first anode connection hole ANCH1.

The second source-drain conductive layer SDCDL2 may include a second anode connection electrode ANCE2.

The second anode connection electrode ANCE2 may be electrically connected to the first anode connection electrode ANCE1 through a second anode connection hole ANCH2.

The element layer 130 may include first electrodes 131 located in the emission areas EA, a pixel defining layer 132 located in the non-emission area NEA and covering edges of the first electrodes 131, first common layers 133 located on the first electrodes 131, light emitting layers 134 located on the first common layers 133, a second common layer 135 located on the pixel defining layer 132 and the light emitting layers 134, and a second electrode 136 located on the second common layer 135.

The element layer 130 may further include auxiliary spacers 132' located on the pixel defining layer 132, and spaced apart from each other.

In this case, the second common layer 135 may be located on the pixel defining layer 132, the auxiliary spacers 132', and the light emitting layers 134.

Each of the light emitting elements LE of the emission areas EA may be formed in a suitable structure in which the first common layer 133, the light emitting layer 134, and the second common layer 135 are interposed between the first electrode 131 and the second electrode 136.

The first electrode 131 may be located on the second planarization layer 126, and may be electrically connected to the second anode connection electrode ANCE2 through a third anode connection hole ANCH3.

Accordingly, the first electrode 131 may be electrically connected to the second electrode portion E26 of the sixth transistor T6 through the first anode connection electrode ANCE1 and the second anode connection electrode ANCE2.

The first electrodes 131 may be located in the emission areas EA, and electrically connected to the light emitting pixel drivers EPD, respectively, and thus, may be referred to as pixel electrodes or anode electrodes.

The second electrode 136 may be located in the entire display area DA including the emission areas EA and the non-emission area NEA, and may be commonly shared by the light emitting elements LE, and thus, may be referred to as a common electrode or a cathode electrode.

Each of the first common layers 133 may include a hole transport layer. Additionally, each of the first common layers 133 may further include a hole injection layer as needed or desired.

The second common layer 135 may include an electron transport layer. Additionally, the second common layer 135 may further include an electron injection layer as needed or desired.

Each of the light emitting layers 134 may include an organic light emitting material.

Each of the pixel defining layer 132 and the auxiliary spacer 132' may include an organic insulating material.

According to an embodiment, the encapsulation layer 140 may include a first encapsulation layer 141 located on the element layer 130 and containing an inorganic insulating material, a second encapsulation layer 142 located on the first encapsulation layer 141 and containing an organic insulating material, and a third encapsulation layer 143 covering the second encapsulation layer 142 and containing an inorganic insulating material.

The touch sensor layer 150 may be located on the encapsulation layer 140. The touch sensor layer 150 may include touch electrodes for detecting a signal that varies depending on a touch of a person or an object, and for sensing a point on the display surface where the touch of the person or the object has occurred.

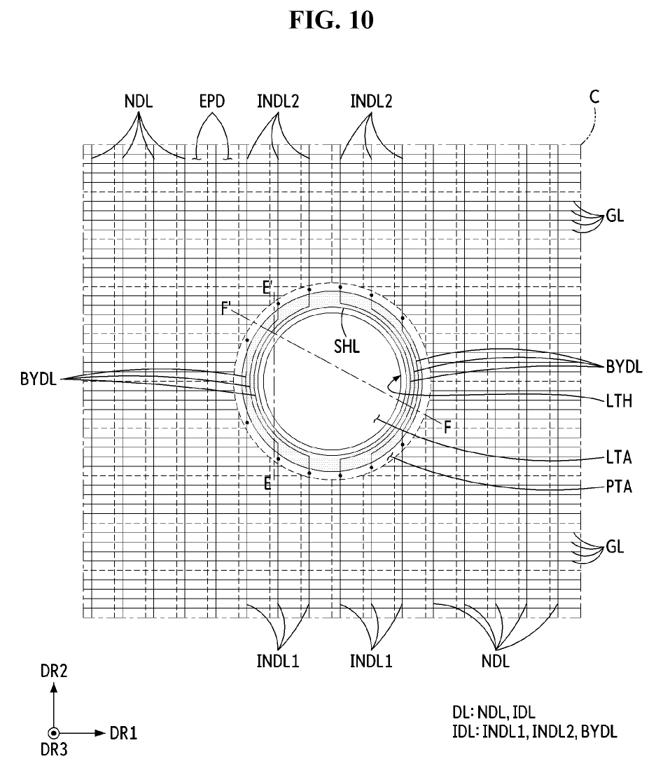

FIG. 10 is a schematic diagram showing an enlarged view of the part C of FIG. 4 according to an embodiment.

FIG. 10 illustrates the light transmitting area LTA, the light transmitting peripheral area PTA, and the first substrate FSUB in a portion of the display area DA adjacent to the light transmitting peripheral area PTA.

As illustrated in FIG. 10, according to an embodiment, the circuit layer 120 may include the light emitting pixel drivers EPD arranged along the first direction DR1 and the second direction DR2 in the display area DA, the data lines DL extending in the second direction DR2 and for transmitting the data signal Vdata (e.g., see FIG. 8) to the light emitting pixel drivers EPD, and a shield line SHL located in the light transmitting peripheral area PTA and for transmitting a constant voltage.

The shield line SHL may have a ring shape surrounding (e.g., around a periphery of) a vicinity of the light transmitting area LTA.

According to an embodiment, the constant voltage transmitted by the shield line SHL may be one of the first power ELVDD (e.g., see FIG. 8), the second power ELVSS, the first initialization voltage VGINT, and/or the second initialization voltage VAINT. However, the present disclosure is not limited thereto, and the constant voltage transmitted by the shield line SHL may be a separate constant voltage having a different voltage level from those of the first power ELVDD (e.g., see FIG. 8), the second power ELVSS, the first initialization voltage VGINT, and the second initialization voltage VAINT.

According to an embodiment, the shield line SHL located in the light transmitting peripheral area PTA may overlap with a portion of each of intersecting data lines IDL crossing or intersecting the light transmitting area LTA and the light transmitting peripheral area PTA among the data lines DL in the third direction DR3.

As such, although portions of the intersecting data lines IDL are arranged adjacent to each other in the light transmitting peripheral area PTA, a signal coupling defect between the intersecting data lines IDL may be reduced by the constant voltage of the shield line SHL. Accordingly, an impact of the signal coupling defect of the intersecting data lines IDL on a display quality may be removed or reduced.

According to an embodiment, the data lines DL may include the intersecting data lines IDL crossing or intersecting the light transmitting area LTA and the light transmitting peripheral area PTA, and normal data lines NDL spaced apart from the light transmitting area LTA and the light transmitting peripheral area PTA in the first direction DR1.

In other words, the data lines DL may include the normal data lines NDL that do not cross or intersect the light transmitting area LTA and the light transmitting peripheral area PTA, and the intersecting data lines IDL that cross or intersect the light transmitting area LTA and the light transmitting peripheral area PTA.

Each of the intersecting data lines IDL may include a first divided data line INDL1, which extends in the second direction DR2 and is located on one side (e.g., a lower side in FIG. 10) of the light transmitting peripheral area PTA in the second direction DR2, a second divided data line INDL2, which extends in the second direction DR2 and is located on another side (e.g., an upper side in FIG. 10) of the light transmitting peripheral area PTA in the second direction DR2, and a bypass data line BYDL, which is located in the light transmitting peripheral area PTA, bypasses the light transmitting area LTA, and electrically connects the first divided data line INDL1 to the second divided data line INDL2.

The bypass data line BYDL may have a curved shape extending along an outer boundary of the light transmitting area LTA.

According to an embodiment, the circuit layer 120 may further include the gate lines GL extending in the first direction DR1.

According to an embodiment, the first substrate FSUB may further include a light transmitting hole LTH overlapping with the light transmitting area LTA.

The light transmitting hole LTH may be formed by removing an opaque material overlapping with the light transmitting area LTA.

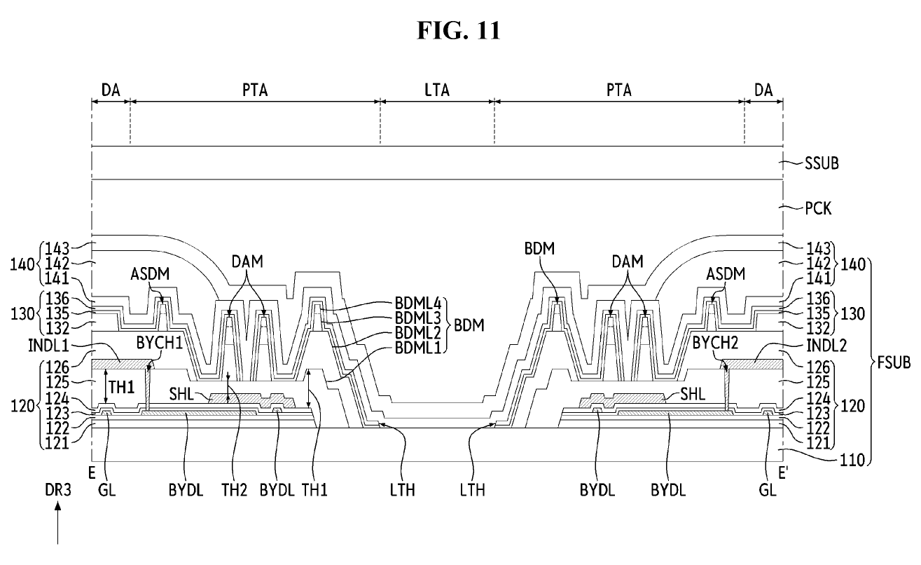

According to an embodiment, the light transmitting hole LTH may be formed in (e.g., may penetrate) the second common layer 135 (e.g., see FIG. 9 and FIG. 11) and the second electrode 136.

Due to the light transmitting hole LTH, a light transmission rate of the light transmitting area LTA may be improved.

FIG. 11 is a cross-sectional view taken along the line E-E’ of FIG. 10 according to an embodiment.

As illustrated in FIG. 11, according to an embodiment, the first substrate FSUB may include two or more light transmitting peripheral dams DAM spaced apart from each other and located in the light transmitting peripheral area PTA.

Each of the two or more light transmitting peripheral dams DAM may be provided in a ring shape surrounding (e.g., around a periphery of) a vicinity of the light transmitting area LTA in the light transmitting peripheral area PTA.

Due to the two or more light transmitting peripheral dams DAM, the second encapsulation layer 142 including the organic insulating material may be spaced apart from the light transmitting area LTA without extending into the light transmitting area LTA.

Accordingly, the third encapsulation layer 143 on the second encapsulation layer 142 may be in contact with the first encapsulation layer 141 in a portion of the light transmitting peripheral area PTA between the two or more light transmitting peripheral dams DAM and the light transmitting area LTA.

According to an embodiment, a portion of the first planarization layer 125 overlapping with the display area DA may have a first thickness range TH1, and another portion of the first planarization layer overlapping with the light transmitting peripheral area PTA may have a second thickness range TH2 that is smaller than the first thickness range TH1.

The two or more light transmitting peripheral dams DAM may be located on the first planarization layer 125 having the second thickness range TH2.

As such, a depth of a valley between the two or more light transmitting peripheral dams DAM may include a difference between the first thickness range TH1 and the second thickness range TH2. Accordingly, a capacity of the second encapsulation layer 142 by the valley between the two or more light transmitting peripheral dams DAM may be increased, so that a possibility of a defect occurrence in which the second encapsulation layer 142 extends beyond the two or more light transmitting peripheral dams DAM into the light transmitting area LTA may be reduced.

The first substrate FSUB may further include an auxiliary dam ASDM located on the second planarization layer 126.

The auxiliary dam ASDM may surround (e.g., around a periphery of) the two or more light transmitting peripheral dams DAM, and may be located adjacent to (e.g., closer to) the display area DA as compared to the two or more light transmitting peripheral dams DAM.

Because an expansion speed of the second encapsulation layer 142 may be delayed by the auxiliary dam ASDM, a possibility of a defect occurrence in which the second encapsulation layer 142 extends beyond the two or more light transmitting peripheral dams DAM into the light transmitting area LTA may be further reduced.

Each of the two or more light transmitting peripheral dams DAM and the auxiliary dam ASDM may include two or more sequentially stacked dam layers.

Each of the two or more dam layers may be in the same layer as that of one of the second planarization layer 126, the pixel defining layer 132, and/or the auxiliary spacer 132'.

According to an embodiment, the circuit layer 120 may include a plurality of inorganic layers 121, 122, 123, and 124 stacked on the support substrate 110.

The plurality of inorganic layers 121, 122, 123, and 124 may include the buffer layer 121, the first gate insulating layer 122, the second gate insulating layer 123, and the first interlayer insulating layer 124.

The plurality of inorganic layers 121, 122, 123, and 124 may extend from the display area DA to a portion of the light transmitting peripheral area PTA, and may be spaced apart from the light transmitting area LTA.

According to an embodiment, in order to cushion external forces that may be applied to the plurality of inorganic layers 121, 122, 123, and 124 that may be relatively vulnerable to cracks, the first substrate FSUB may further include a border dam BDM adjacent to the edge of the light transmitting area LTA, and covering cross-sections of the plurality of inorganic layers 121, 122, 123, and 124.

The border dam BDM may include two or more border dam layers BDML1, BDML2, BDML3, and BDML4 stacked sequentially.

For example, the border dam BDM may include a first border dam layer BDML1 formed in the same layer as that of the first planarization layer 125 having the first thickness range TH1, a second border dam layer BDML2 formed in the same layer as that of the second planarization layer 126, a third border dam layer BDML3 formed in the same layer as that of the pixel defining layer 132, and a fourth border dam layer BDML4 formed in the same layer as that of the auxiliary spacer 132'.

In other words, the first border dam layer BDML1 of the border dam BDM may be formed in the same layer as that of the first planarization layer 125 having the first thickness range TH1 overlapping with the display area DA, rather than that of the first planarization layer 125 having the second thickness range TH2 overlapping with the light transmitting peripheral area PTA. As such, a cushioning effect of an external force that may be applied to the plurality of inorganic layers 121, 122, 123, and 124 may be improved.

According to an embodiment, among the data lines DL, the remaining lines except for the bypass data lines BYDL of the intersecting data lines IDL may be located in the second source-drain conductive layer SDCDL2 on the first planarization layer 125.

In other words, each of the normal data lines NDL (e.g., see FIG. 10), the first divided data lines INDL1 of the intersecting data lines IDL, and the second divided data lines INDL2 of the intersecting data lines IDL may be located in the second source-drain conductive layer SDCDL2 (e.g., see FIG. 9) on the first planarization layer 125.

Each of the bypass data lines BYDL of the intersecting data lines IDL may be located in one of the first gate conductive layer GCDL1 (e.g., see FIG. 9) on the first gate insulating layer 122 and/or the second gate conductive layer GCDL2 on the second gate insulating layer 123.

In each of the intersecting data lines IDL, one end of the bypass data line BYDL may be electrically connected to the first divided data line INDL1 through a first bypass connection hole BYCH1, and another end of the bypass data line BYDL may be electrically connected to the second divided data line INDL2 through a second bypass connection hole BYCH2.

When the bypass data line BYDL is located in the second gate conductive layer GCDL2 (e.g., see FIG. 9) on the second gate insulating layer 123, each of the first bypass connection hole BYCH1 and the second bypass connection hole BYCH2 may be formed in (e.g., may penetrate) the first planarization layer 125 and the first interlayer insulating layer 124.

As another example, when the bypass data line BYDL is located in the first gate conductive layer GCDL1 (e.g., see FIG. 9) on the first gate insulating layer 122, each of the first bypass connection hole BYCH1 and the second bypass connection hole BYCH2 may be formed in (e.g., may penetrate) the first planarization layer 125, the first interlayer insulating layer 124, and the second gate insulating layer 123.

Accordingly, in each of the intersecting data lines IDL, the first divided data line INDL1 and the second divided data line INDL2, which are separated (e.g., space apart) from each other by the light transmitting peripheral area PTA, may be electrically connected to each other by the bypass data line BYDL.

According to an embodiment, the second common layer 135 and the second electrode 136 of the element layer 130 may be entirely located in the display area DA.

Accordingly, in the process of arranging the second common layer 135 and the second electrode 136, the second common layer 135 and the second electrode 136 may be formed in the entire display area DA through a mask corresponding to the display area DA.

In this case, because the second common layer 135 and the second electrode 136 overlap with the light transmitting area LTA, the light transmitting hole LTH may be formed through a process of partially removing the second common layer 135 and the second electrode 136 before arranging the first encapsulation layer 141.

In other words, according to an embodiment, the light transmitting hole LTH may be formed in (e.g., may penetrate) the second common layer 135 and the second electrode 136.

Due to the light transmitting hole LTH, a part of each of the second common layer 135 and the second electrode 136 overlapping with the light transmitting area LTA may be removed, so that the light transmission rate of the light transmitting area LTA may be improved.

According to an embodiment, the first encapsulation layer 141 and the third encapsulation layer 143 of the encapsulation layer 140 may be entirely located in the display area DA.

In other words, the first encapsulation layer 141 and the third encapsulation layer 143 may extend to the light transmitting area LTA.

Accordingly, the third encapsulation layer 143 may be in contact with the first encapsulation layer 141 in the light transmitting area LTA.

In addition, the first encapsulation layer 141 may be in contact with the support substrate 110 through the light transmitting hole LTH in the light transmitting area LTA.

Accordingly, an inorganic bonding structure may be formed by the support substrate 110, the first encapsulation layer 141, and the third encapsulation layer 143.

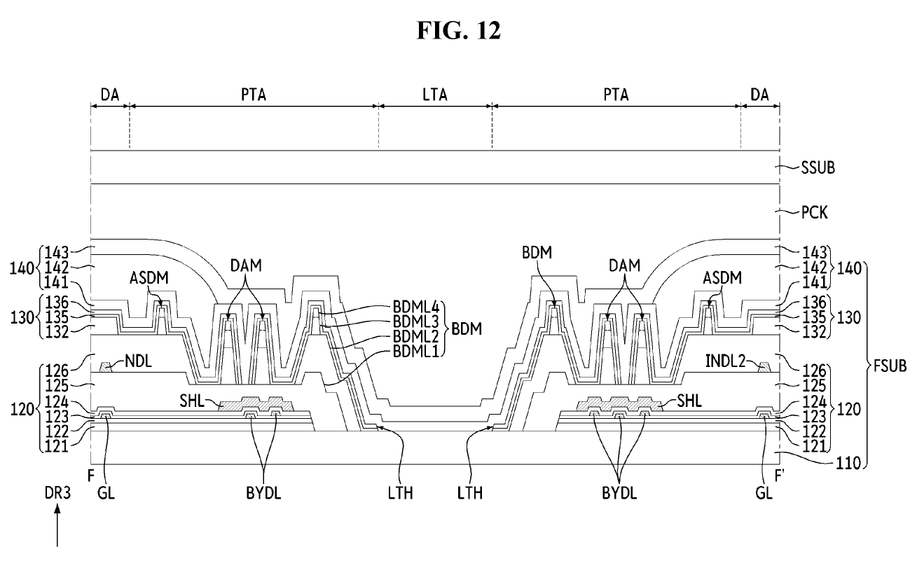

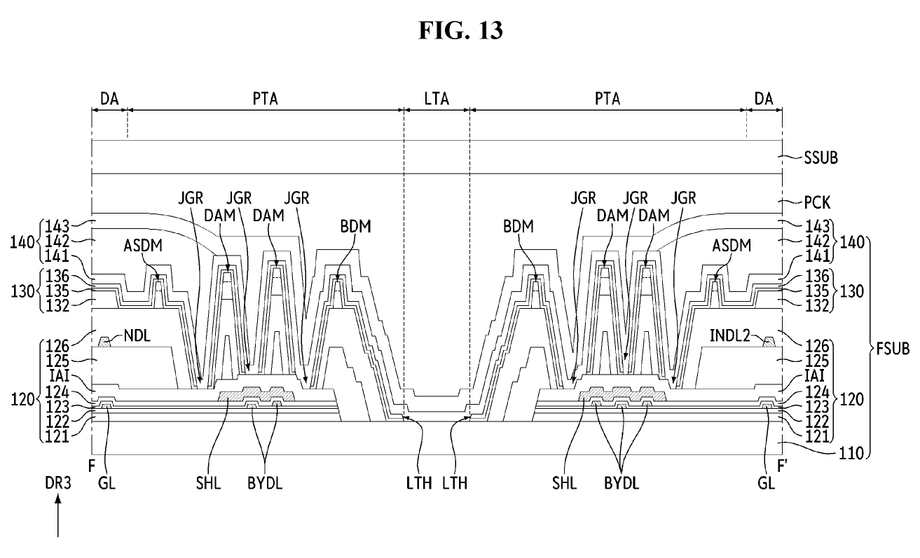

FIGS. 12 and 13 are cross-sectional views taken along the line F-F' of FIG. 10 according to some embodiments.

According to an embodiment as illustrated in FIG. 12, the shield line SHL may be located in the first source-drain conductive layer SDCDL1 (e.g., see FIG. 9) on the first interlayer insulating layer 124.

According to the embodiment of FIG. 12, the first planarization layer 125 having the second thickness range TH2 may cover the shield line SHL located on the first interlayer insulating layer 124 of the light transmitting peripheral area PTA.

The display device 100 illustrated in FIG. 13 is the same or substantially the same as (or similar to) the display device 100 described above with reference to FIGS. 10, 11, and 12, except that the circuit layer 120 is located between the first source-drain conductive layer SDCDL1 (e.g., see FIG. 9) and the first planarization layer 125, and further includes an inorganic auxiliary insulating layer IAI including an inorganic insulating material, and the first encapsulation layer 141 is in contact with the inorganic auxiliary insulating layer IAI through bonding grooves JGR formed in the second common layer 135 and the second electrode 136. Accordingly, redundant description thereof may not be repeated hereinafter.

The inorganic auxiliary insulating layer IAI may be located on the first interlayer insulating layer 124, and may cover the first source-drain conductive layer SDCDL1 (e.g., see FIG. 9).

Accordingly, the shield line SHL located in the first source-drain conductive layer SDCDL1 (e.g., see FIG. 9) may be covered with the inorganic auxiliary insulating layer IAI.

The first planarization layer 125 may overlap with at least the display area DA, and may cover a part of the inorganic auxiliary insulating layer IAI.

The bonding grooves JGR may be located in a separation area between the two or more light transmitting peripheral dams DAM, and on opposite sides of the two or more light transmitting peripheral dams DAM.

Accordingly, each of the bonding grooves JGR may be provided in a ring shape surrounding (e.g., around a periphery of) the light transmitting area LTA, similarly to that of the two or more light transmitting peripheral dams DAM.

According to an embodiment, the bonding grooves JGR may be formed by partially removing the second common layer 135 and the second electrode 136 through a laser irradiation process.

Because the laser irradiation process is performed relatively excessively, such that the bonding groove JGR is formed in the second common layer 135 and the second electrode 136, the inorganic auxiliary insulating layer IAI may be exposed to the laser irradiation process through the bonding groove JGR.

However, the inorganic auxiliary insulating layer IAI may include an inorganic insulating material, and thus, may have a higher etch ratio than those of the second common layer 135 and the second electrode 136 with respect to the laser irradiation process. Accordingly, although a separate etch stopper may not be located for the laser irradiation process, the inorganic auxiliary insulating layer IAI may not be significantly damaged even by the excessive laser irradiation process.

Accordingly, the shield line SHL covered with the inorganic auxiliary insulating layer IAI may be protected from the laser irradiation process by the inorganic auxiliary insulating layer IAI.

Additionally, according to an embodiment, the inorganic auxiliary insulating layer IAI may be located to have a thickness greater than those of the first gate insulating layer 122, the second gate insulating layer 123, and the first interlayer insulating layer 124.

As such, heat generated by the excessive laser irradiation process is transmitted to the shield line SHL, so that a defect in which the shield line SHL is broken or damaged may be reduced.

The first encapsulation layer 141 may be in contact with the inorganic auxiliary insulating layer IAI through the bonding grooves JGR.

Accordingly, inorganic bonding structures by the first encapsulation layer 141 and the inorganic auxiliary insulating layer IAI may be formed in the light transmitting peripheral area PTA, so that a defect in which oxygen or moisture permeates from the light transmitting area LTA may be reduced.

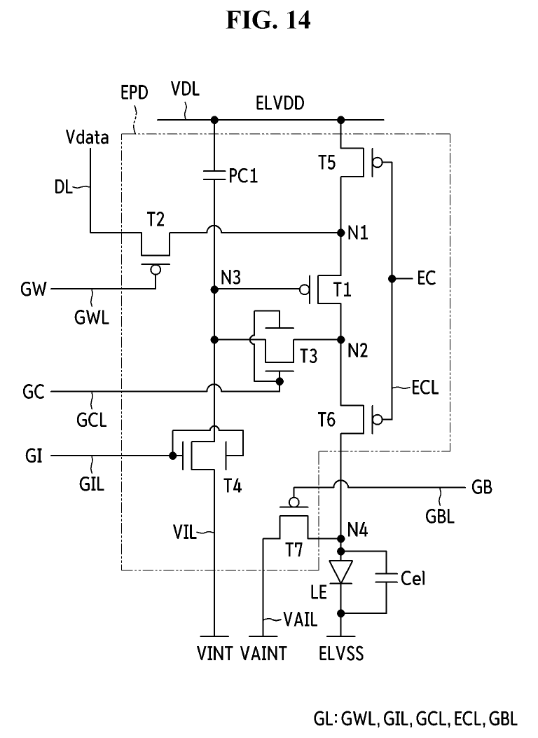

FIG. 14 is an equivalent circuit diagram showing a light emitting pixel driver of FIG. 7 according to an embodiment.

Referring to FIG. 14, the display device 100 may be the same or substantially the same as (or similar to) that described above with reference to FIG. 8, except that in each of the light emitting pixel drivers EPD of the circuit layer 120, the third transistor T3 and the fourth transistor T4 may be formed as N-type MOSFETs, the gate electrode of the third transistor T3 may be electrically connected to the gate control line GCL for transmitting the gate control signal GC, and the gate electrode of the seventh transistor T7 may be electrically connected to a bias control line GBL for transmitting a bias control signal GB. Accordingly, redundant description thereof may not be repeated hereinafter.

According to an embodiment illustrated in FIG. 14, in each of the light emitting pixel drivers EPD, the first transistor T1, the second transistor T2, the fifth transistor T5, the sixth transistor T6, and the seventh transistor T7 may be formed as P-type MOSFETs, and the third transistor T3 and the fourth transistor T4 may be formed as N-type MOSFETs.

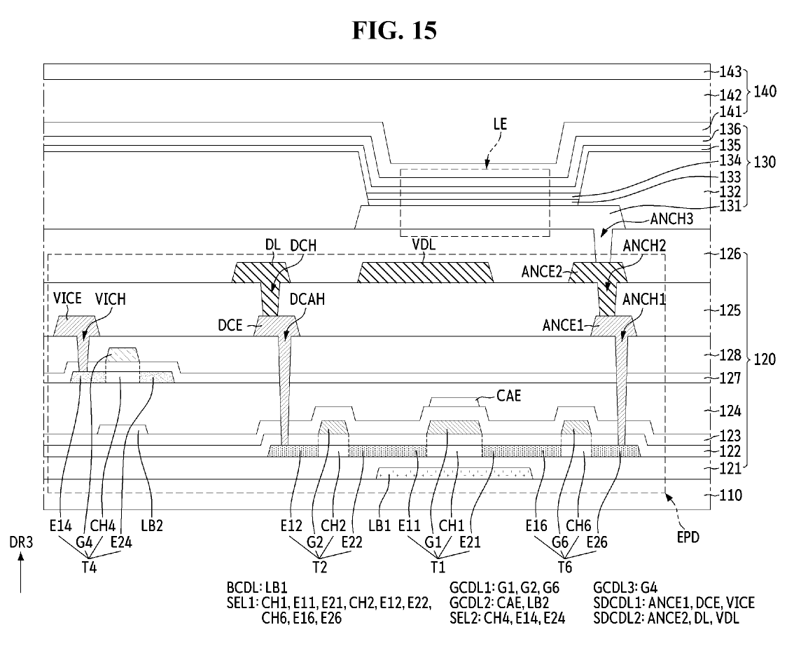

Accordingly, the circuit layer 120 may include the first semiconductor layer SEL1 for forming a P-type MOSFET, and a second semiconductor layer SEL2 (e.g., see FIG. 15) for forming an N-type MOSFET.

FIG. 15 is a cross-sectional view showing the light emitting pixel driver and a light emitting element of FIG. 14 according to an embodiment.

Referring to FIG. 15, the display device 100 according to an embodiment may be the same or substantially the same as (or similar to) that described above with reference to FIG. 9, except that the circuit layer 120 may further include the second semiconductor layer SEL2, a third gate insulating layer 127, a third gate conductive layer GCDL3, and a second interlayer insulating layer 128 located between the first interlayer insulating layer 124 and the first source-drain conductive layer SDCDL1. Accordingly, redundant description thereof may not be repeated hereinafter.

According to an embodiment, the circuit layer 120 may further include the second semiconductor layer SEL2 located on the first interlayer insulating layer 124, the third gate insulating layer 127 covering the second semiconductor layer SEL2, the third gate conductive layer GCDL3 located on the third gate insulating layer 127, and the second interlayer insulating layer 128 covering the third gate conductive layer GCDL3.

The first source-drain conductive layer SDCDL1 may be located on the second interlayer insulating layer 128.

According to an embodiment, each of the third gate insulating layer 127 and the second interlayer insulating layer 128 may include an inorganic insulating material.

The first semiconductor layer SEL1 may include the channel portions CH1, CH2, and CH6, the first electrode portions E11, E12, and E16, and the second electrode portions E21, E22, and E26 of the first transistor T1, the second transistor T2, and the sixth transistor T6.

The first electrode portion E11 of the first transistor T1 may be connected to the second electrode portion E22 of the second transistor T2.

The second electrode portion E21 of the first transistor T1 may be connected to the first electrode portion E16 of the sixth transistor T6.

According to an embodiment, the circuit layer 120 may further include a first light blocking layer LB1 located on the support substrate 110 and overlapping with the channel portion CH1 of the first transistor T1.

The buffer layer 121 may cover the first light blocking layer LB1.

The first gate conductive layer GCDL1 may include the gate electrodes G1, G2, and G6 of the first transistor T1, the second transistor T2, and the sixth transistor T6.

Because the fifth transistor T5 and the seventh transistor T7 may be formed as P-type MOSFETs, similarly to those of the first transistor T1, the second transistor T2, and the sixth transistor T6, the first semiconductor layer SEL1 may further include a channel portion, a first electrode portion, and a second electrode portion of each of the fifth transistor T5 and the seventh transistor T7, and the first gate conductive layer GCDL1 may further include a gate electrode of each of the fifth transistor T5 and the seventh transistor T7.

The second gate conductive layer GCDL2 may include a capacitor electrode CAE.

The second semiconductor layer SEL2 may include a channel portion CH4, a first electrode portion E14, and a second electrode portion E24 of the fourth transistor T4.

The third gate conductive layer GCDL3 may include the gate electrode G4 of the fourth transistor T4.

The circuit layer 120 may further include a second light blocking layer LB2 located in the second gate conductive layer GCDL2 and overlapping with the channel portion CH4 of the fourth transistor T4.

The channel portion CH4 of the fourth transistor T4 may be interposed between the second light blocking layer LB2 and the gate electrode G4 of the fourth transistor T4 in the third direction DR3.

Accordingly, the second light blocking layer LB2 may not be in a floating state, and may be an auxiliary gate electrode of the fourth transistor T4.

Because the third transistor T3, similarly to the fourth transistor T4, may be formed as an N-type MOSFET, the second semiconductor layer SEL2 may further include a channel portion, a first electrode portion, and a second electrode portion of the third transistor T3, and the third gate conductive layer GCDL3 may further include a gate electrode of the third transistor T3.

The first source-drain conductive layer SDCDL1 may include the first anode connection electrode ANCE1, a data connection electrode DCE, and an initialization connection electrode VICE.

The first anode connection electrode ANCE1 may be electrically connected to the second electrode portion E26 of the sixth transistor T6 through a first anode connection hole ANCH1.

The data connection electrode DCE may be electrically connected to the first electrode portion E12 of the second transistor T2 through the data connection auxiliary hole DCAH.

The initialization connection electrode VICE may be electrically connected to the first electrode portion E14 of the fourth transistor T4 through an initialization connection hole VICH.

The second source-drain conductive layer SDCDL2 may include the second anode connection electrode ANCE2, the data line DL, and the first power line VDL.

The second anode connection electrode ANCE2 may be electrically connected to the first anode connection electrode ANCE1 through the second anode connection hole ANCH2.

The first electrode 131 of the element layer 130 may be located on the second planarization layer 126, and may be electrically connected to the second anode connection electrode ANCE2 through the third anode connection hole ANCH3.

Accordingly, the first electrode 131 may be electrically connected to the second electrode portion E26 of the sixth transistor T6 through the first anode connection electrode ANCE1 and the second anode connection electrode ANCE2.

The data line DL may be electrically connected to the data connection electrode DCE through the data connection hole DCH.

Accordingly, the data line DL may be electrically connected to the first electrode portion E12 of the second transistor T2 through the data connection electrode DCE.

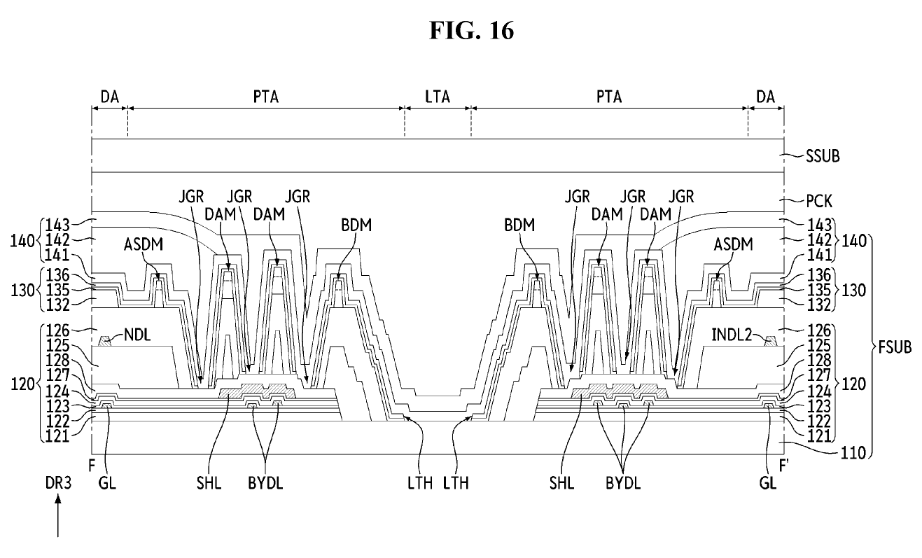

FIGS. 16 to 22 are cross-sectional views taken along the line F-F' of FIG. 10 according to some embodiments.

Referring to FIG. 16, the display device 100 may be the same or substantially the same as (or similar to) the display device 100 described above with reference to FIG. 13, except that the shield line SHL may be located in the third gate conductive layer GCDL3 (e.g., see FIG. 15) on the third gate insulating layer 127. Accordingly, redundant description thereof may not be repeated hereinafter.

As such, the shield line SHL may be covered with the second interlayer insulating layer 128 including an inorganic insulating material. Accordingly, the shield line SHL may be protected from the laser irradiation process for forming the bonding groove JGR by the second interlayer insulating layer 128.

Accordingly, there may be no need to separately arrange an inorganic insulating layer to protect the shield line SHL from the laser irradiation process for forming the bonding groove JGR.

Accordingly, the manufacturing process of the display device 100 including the shield line SHL may be simplified.

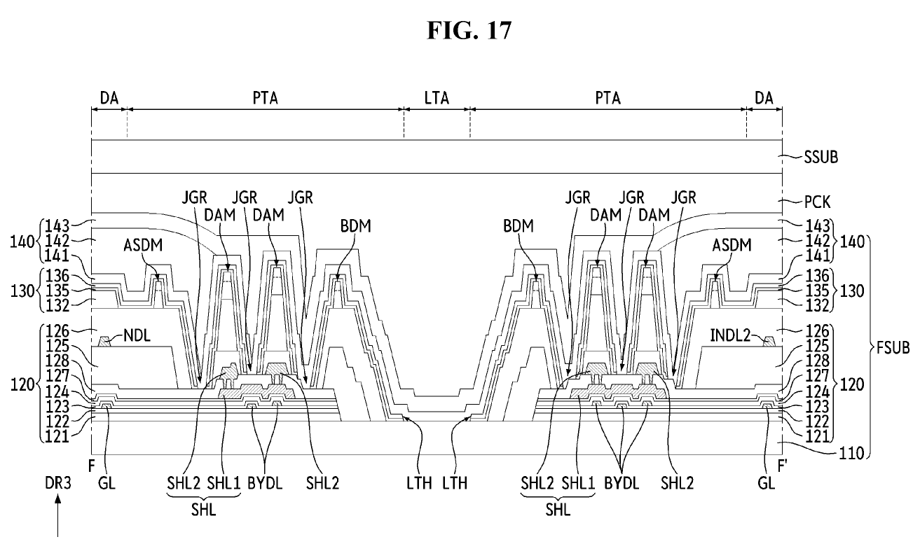

Referring to FIG. 17, the display device 100 may be the same or substantially the same as (or similar to) the display device 100 described above with reference to FIG. 16, except that the shield line SHL may include a first shield layer SHL1 located in the third gate conductive layer GCDL3 (e.g., see FIG. 15) on the third gate insulating layer 127, and at least one second shield layer SHL2 located in the first source-drain conductive layer SDCDL1 on the second interlayer insulating layer 128 and electrically connected to the first shield layer SHL1. Accordingly, redundant description thereof may not be repeated hereinafter.

In an embodiment, two or more light transmitting peripheral dams DAM may cover at least one second shield layer SHL2.

In other words, at least one second shield layer SHL2 may be covered by at least one of the two or more light transmitting peripheral dams DAM, and thus, may not be exposed through the bonding groove JGR located between the two or more light transmitting peripheral dams DAM.

At least one second shield layer SHL2 may be electrically connected to the first shield layer SHL1 through connection holes formed in the second interlayer insulating layer 128.

As such, because the shield line SHL may have a relatively smaller resistance compared to its limited area, the constant voltage transmitted through the shield line SHL may be more stably maintained. Accordingly, the signal coupling defect between the intersecting data lines IDL may be further reduced.

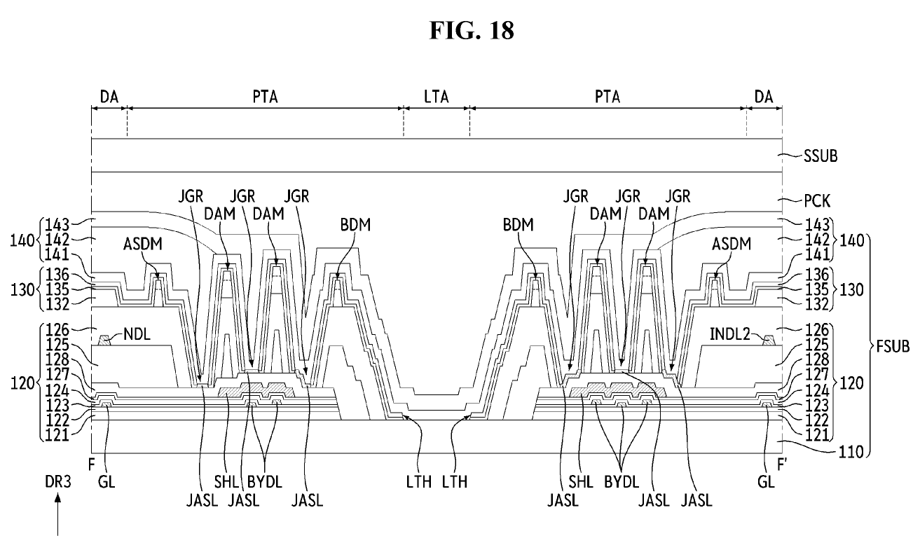

Referring to FIG. 18, the display device 100 may be the same or substantially the same as (or similar to) the display device 100 described above with reference to FIG. 16, except that the circuit layer 120 may further include bonding auxiliary layers JASL, and the bonding grooves JGR may overlap with the bonding auxiliary layers JASL. Accordingly, redundant description thereof may not be repeated hereinafter.

The bonding auxiliary layers JASL may be located in a separation area between the two or more light transmitting peripheral dams DAM, and on opposite sides of the two or more light transmitting peripheral dams DAM.

Each of the bonding auxiliary layers JASL may have a ring shape surrounding (e.g., around a periphery of) the light transmitting area LTA, similarly to that of the two or more light transmitting peripheral dams DAM.

The bonding auxiliary layers JASL may be located on the second interlayer insulating layer 128 of the light transmitting peripheral area PTL.

The bonding auxiliary layers JASL may help seal around the light transmitting hole LTH, and protect the second interlayer insulating layer 128 from the laser irradiation process for forming the bonding groove JGR.

According to an embodiment, in the laser irradiation process for forming the bonding groove JGR, the bonding auxiliary layers JASL may be used as an etch stopper.

Accordingly, the second interlayer insulating layer 128 and the shield line SHL located thereunder may be protected by the bonding auxiliary layers JASL from the laser irradiation process.

According to an embodiment, the first encapsulation layer 141 may be in contact with the bonding auxiliary layers JASL through the bonding grooves JGR.

Accordingly, inorganic bonding structures by the first encapsulation layer 141 and the bonding auxiliary layers JASL may be formed in the light transmitting peripheral area PTA, so that a defect in which oxygen or moisture permeates from the light transmitting area LTA may be reduced.

For example, two or more of the bonding auxiliary layers JASL may include titanium (Ti).

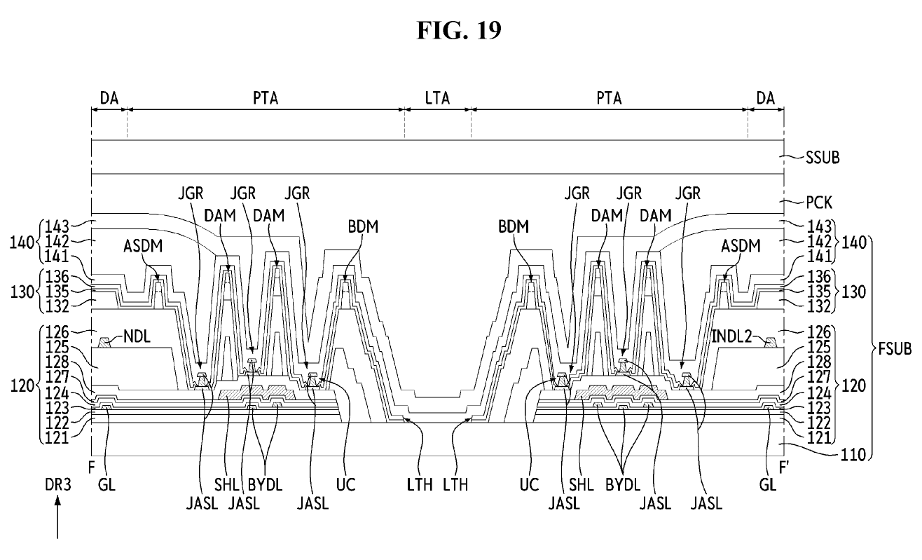

Referring to FIG. 19, the display device 100 may be the same or substantially the same as (or similar to) the display device 100 described above with reference to FIG. 18, except that each of the bonding auxiliary layers JASL may include an undercut structure UC. Accordingly, redundant description thereof may not be repeated hereinafter.

According to an embodiment as illustrated in FIG. 19, each of the bonding auxiliary layers JASL may include the undercut structure UC formed by a main layer located on the second interlayer insulating layer 128 of the light transmitting peripheral area PTA, and a roof layer located on the main layer and protruding beyond the main layer.

Due to the undercut structure UC of each of the bonding auxiliary layers JASL, in each of two or more bonding auxiliary layers JASL, the second common layer 135 and the second electrode 136 may not cover the entire side surface of the main layer, and may be partially located only in the lower part of the side surface of the main layer, which an influence of the roof layer is relatively low.

As a result, the first encapsulation layer 141 may be in contact with a portion (e.g., an upper portion) of the side surface of the main layer, which is adjacent to the roof layer, in each of the bonding auxiliary layers JASL.

Accordingly, inorganic bonding structures by the first encapsulation layer 141 and the bonding auxiliary layers JASL may be formed in the light transmitting peripheral area PTA.

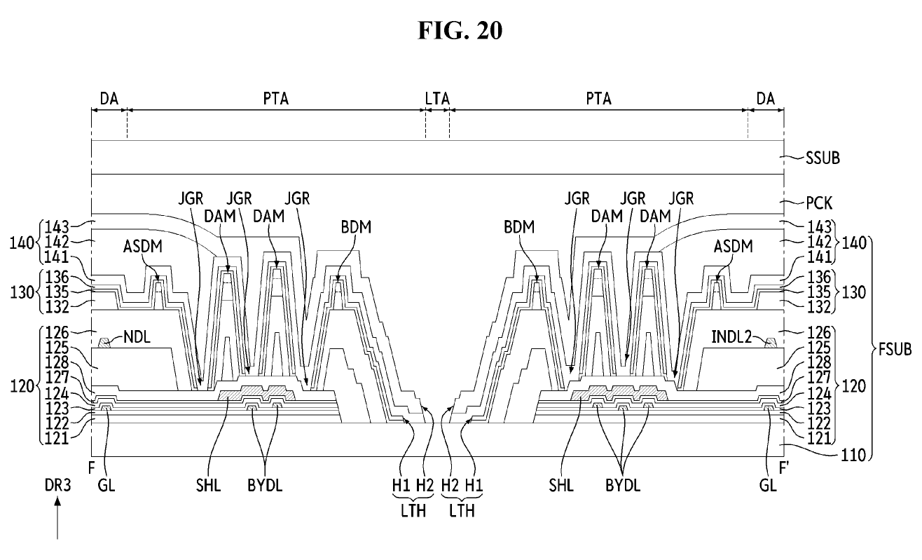

Referring to FIG. 20, the display device 100 may be the same or substantially the same as (or similar to) the display device 100 described above with reference to FIG. 16, except that the light transmitting hole LTH may include a first hole H1 and a second hole H2. Accordingly, redundant description thereof may not be repeated hereinafter.

According to an embodiment, the light transmitting hole LTH may include the first hole H1 formed in the second common layer 135 and the second electrode 136, and the second hole H2 formed in the first encapsulation layer 141 and the third encapsulation layer 143.

For example, a width of the second hole H2 may be less than that of the first hole H1.

As such, the first encapsulation layer 141 and the third encapsulation layer 143 may overlap with a part of the light transmitting area LTA, and the first encapsulation layer 141 overlapping with a part of the light transmitting area LTA may be in contact with the support substrate 110 through the first hole H1.

The third encapsulation layer 143 may be in contact with the first encapsulation layer 141 in a part of the light transmitting area LTA.

Accordingly, an inorganic bonding structure by the support substrate 110, the first encapsulation layer 141, and the third encapsulation layer 143 may be formed in the light transmitting area LTA, so that a defect in which oxygen or moisture permeates from the light transmitting area LTA may be reduced.

Additionally, a portion of each of the first encapsulation layer 141 and the third encapsulation layer 143 overlapping with the light transmitting area LTA may be removed by the second hole H2.

Accordingly, the filling layer PCK may be in contact with the support substrate 110 through the light transmitting hole LTH.

As such, a number of interfaces overlapping with the light transmitting area LTA may be reduced, so that the light transmission rate of the light transmitting area LTA may be improved.

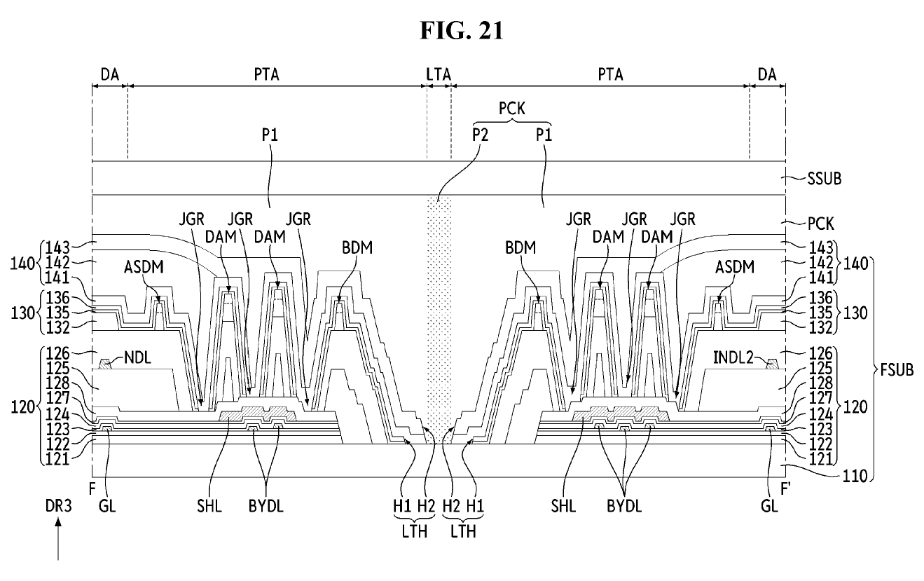

Referring to FIG. 21, the display device 100 may be the same or substantially the same as (or similar to) the display device 100 described above with reference to FIG. 20, except that the filling layer PCK includes a first filling portion P1 overlapping with the display area DA and the light transmitting peripheral area PTA, and a second filling portion P2 overlapping with the light transmitting area LTA. Accordingly, redundant description thereof may not be repeated hereinafter.

According to an embodiment, the first filling portion P1 may include a first transparent material.

The second filling portion P2 may include a second transparent material having a higher refractive index than that of the first transparent material.

As such, at least part of the light may be blocked at the interface between the first filling portion P1 and the second filling portion P2. Accordingly, a light leakage defect in which light from the display area DA is introduced into the light transmitting area LTA may be reduced, so that a display quality deterioration due to the light leakage defect may be prevented, and the deterioration of the sensing accuracy of the optical device 18 may be prevented.

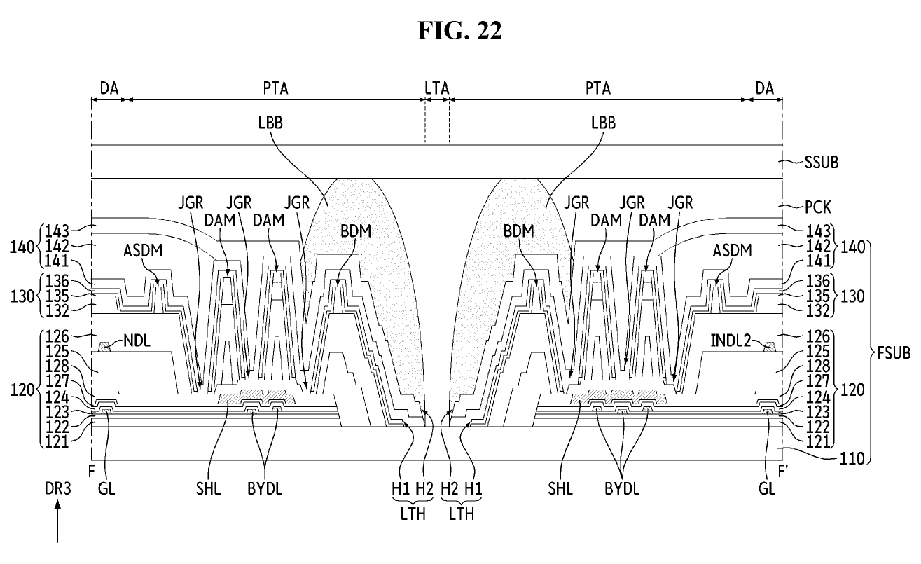

Referring to FIG. 22, the display device 100 may be the same or substantially the same as (or similar to) the display device 100 described above with reference to FIG. 20, except that a light blocking bank LBB may be further included. The light blocking bank LBB may be located between the first substrate FSUB and the second substrate SSUB, and may overlap with at least a portion of the two or more light transmitting peripheral dams DAM. Accordingly, redundant description thereof may not be repeated hereinafter.

According to an embodiment, the light blocking bank LBB may overlap with the border dam BDM.

The light blocking bank LBB may include at least one of a light blocking material that blocks light, a light absorbing material that absorbs light, or a transparent material having a higher refractive index than that of the filling layer PCK.

According to an embodiment, the light blocking bank LBB may cover the edge of the light transmitting hole LTH. In other words, the cross-sections of the third encapsulation layer 143 and the first encapsulation layer 141 corresponding to the edge of the light transmitting hole LTH may be covered by the light blocking bank LBB.

In other words, the light blocking bank LBB may be in contact with the support substrate 110 through the light transmitting hole LTH.

Accordingly, because the cross-sections of the third encapsulation layer 143 and the first encapsulation layer 141 are not exposed to light of the light transmitting area LTA, a light leakage defect in which light from the light transmitting area LTA enters the display area DA through the third encapsulation layer 143 and the first encapsulation layer 141 may be prevented.

As such, according to an embodiment, a light leakage defect in which light from the light transmitting area LTA enters the display area DA and a light leakage defect in which light from the display area DA enters the light transmitting area LTA may be prevented by the light blocking bank LBB.

Accordingly, a degradation in a display quality due to light leakage defects may be prevented, and a reduction in a sensing accuracy of the optical device 18 may be prevented.

As described above the shield line SHL may be located over the data bypass lines BYDL, but the present disclosure is not limited thereto. For example, in some embodiments, the shield line SHL may be formed in the same layer as that of the first light blocking layer LB1 (e.g., see FIG. 15) on the support substrate 110, and the data bypass lines BYDL may be located over the shield line SHL.

Additionally, as described above, the shield line SHL and two or more light transmitting peripheral dams DAM may overlap with the data bypass lines BYDL that are portions of the data lines DL. However, the present disclosure is not limited thereto, and the circuit layer 120 may include gate bypass lines that are located in the light transmitting peripheral area PTA among the gate lines GL and bypass the light transmitting area LTA, and the shield line SHL and two or more light transmitting peripheral dams DAM may overlap with the gate bypass lines that are portions of the gate lines GL.

The display device 100 according to some embodiments as described above may be applied to various suitable electronic devices 10.

The electronic device 10 according to an embodiment may include the display device 100 as described above.

Additionally, the electronic device 10 according to an embodiment may further include a module or a device having other additional functions in addition to the display device 100.

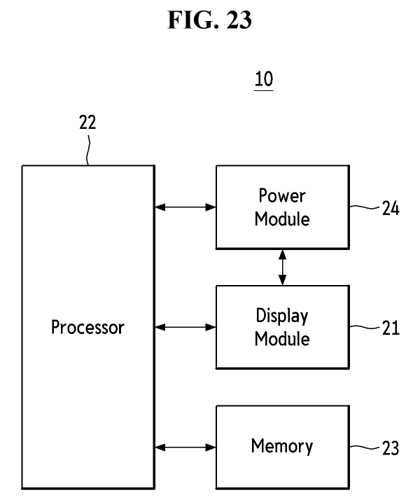

FIG. 23 is a block diagram of an electronic device according to an embodiment.

Referring to FIG. 23, an electronic device 10 according to an embodiment may include a display module (e.g., a display or a touch-display) 21, a processor 22, a memory 23, and a power module (e.g., a power supply or a power circuit) 24.

The display module 21 may include the display device 100 for displaying an image.

The processor 22 may include at least one of a central processing unit (CPU), an application processor (AP), a graphic processing unit (GPU), a communication processor (CP), an image signal processor (ISP), or a controller.

The memory 23 may store data information used for the operation of the processor 22 or the display module 21. When the processor 22 executes an application stored in the memory 23, an image data signal and/or an input control signal may be transmitted to the display module 21, and the display module 21 may process the received signal and output image information through a display screen.

The power module 24 may include a power supply module, such as a power adapter or a battery device, and a power conversion module that converts the power supplied by the power supply module to generate power used for the operation of the electronic device 10.

At least one of the components of the electronic device 10 described above may be included in the display device according to some embodiments described above. Further, some of individual modules functionally included in one module may be included in the display device, and some others may be provided separately from the display device. For example, the display device 100 may include the display module 21, and the processor 22, the memory 23, and the power module 24 may be provided in the form of other devices in the electronic device 10 other than the display device 100.

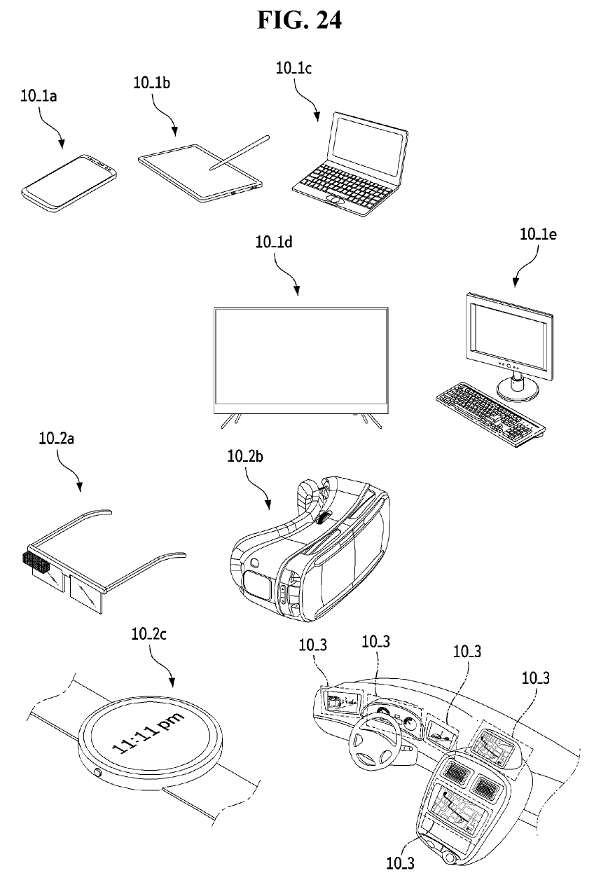

FIG. 24 is schematic views of some electronic devices according to some embodiments.

Referring to FIG. 24, the electronic devices 10 according to some embodiments may include not only an image display electronic device, such as a smartphone 10_1a, a tablet PC 10_1b, a laptop 10_1c, a TV 10_1d, and a desk monitor 10_1e, but also a wearable electronic device, such as smart glasses 10_2a, a head mounted display 10_2b, and a smart watch 10_2c, and a vehicle electronic device 10_3, such as a dashboard of a vehicle, a center fascia, a center information display (CID) of the dashboard, and a room mirror display.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a first substrate;
a second substrate facing and bonded to the first substrate, each of the first substrate and the second substrate comprising:
a display area comprising emission areas;
a non-display area around the display area;
a light transmitting area surrounded around by the display area; and
a light transmitting peripheral area between the light transmitting area and the display area; and
a filling layer filled between the first substrate and the second substrate,
wherein the first substrate further comprises:
a support substrate;
a circuit layer on the support substrate; and
two or more light transmitting peripheral dams in the light transmitting peripheral area, and spaced from each other,
wherein the circuit layer comprises:
light emitting pixel drivers along a first direction and a second direction in the display area;
data lines extending in the second direction, and configured to transmit data signals to the light emitting pixel drivers; and
a shield line in the light emitting peripheral area, configured to transmit a constant voltage, and overlapping with some of the data lines in a third direction, and
wherein the two or more light transmitting peripheral dams overlap with the shield line in the third direction.

2. The display device of claim 1, wherein the data lines comprise:
intersecting data lines, each comprising:
a bypass data line overlapping with the light emitting peripheral area;
a first divided data line facing one side of the light transmitting peripheral area in the second direction; and
a second divided data line facing another side of the light transmitting peripheral area in the second direction, and electrically connected to the first divided data line through the bypass data line; and
normal data lines spaced from the light transmitting area and the light transmitting peripheral area in the first direction
wherein the shield line is located between the bypass data lines of the intersecting data lines and the two or more light transmitting peripheral dams in the third direction.

3. The display device of claim 2, wherein the first substrate further comprises:
an element layer on the circuit layer;
an encapsulation layer covering the element layer; and
a light transmitting hole overlapping with the light transmitting area,
wherein the element layer comprises:
first electrodes in the emission areas, and electrically connected to the light emitting pixel drivers, respectively;
a pixel defining layer in a non-emission area between the emission areas of the display area, and covering edges of the first electrodes;
first common layers on the first electrodes;
light emitting layers on the first common layers;
a second common layer on the pixel defining layer and the light emitting layers; and
a second electrode on the second common layer,
wherein the encapsulation layer comprises:
a first encapsulation layer on the element layer, and comprising an inorganic insulating material;
a second encapsulation layer on the first encapsulation layer, and comprising an organic insulating material; and
a third encapsulation layer covering the second encapsulation layer, and comprising an inorganic insulating material,
wherein the second encapsulation layer is spaced from the light transmitting area by the two or more light transmitting peripheral dams,
wherein the light transmitting hole penetrates the second common layer and the second electrode, and
wherein, in a portion of the light transmitting peripheral area between the two or more light transmitting peripheral dams and the light transmitting area, the third encapsulation layer is in contact with the first encapsulation layer.

4. The display device of claim 3, wherein the circuit layer comprises:
a first semiconductor layer on the support substrate;
a first gate insulating layer covering the first semiconductor layer;
a first gate conductive layer on the first gate insulating layer;
a second gate insulating layer covering the first gate conductive layer;
a second gate conductive layer on the second gate insulating layer;
a first interlayer insulating layer covering the second gate conductive layer;
a first source-drain conductive layer on the first interlayer insulating layer;
a first planarization layer covering the first source-drain conductive layer;
a second source-drain conductive layer on the first planarization layer; and
a second planarization layer covering the second source-drain conductive layer,
wherein each of the first gate insulating layer, the second gate insulating layer, and the interlayer insulating layer comprises an inorganic insulating material,
wherein each of the normal data lines, the first divided data lines of the intersecting data lines, and the second divided data lines of the intersecting data lines is located in the second source-drain conductive layer, and
wherein each of the bypass data lines is located in one of the first gate conductive layer or the second gate conductive layer.

5. The display device of claim 4, wherein the shield line is located in the first source-drain conductive layer.

6. The display device of claim 5, wherein a portion of the first planarization layer overlapping with the display area has a first thickness range, and another portion of the first planarization layer overlapping with the light transmitting peripheral area has a second thickness range smaller than the first thickness range,
wherein the first planarization layer having the second thickness range covers the shield line, and
wherein the two or more light transmitting peripheral dams are located on the first planarization layer having the second thickness range.

7. The display device of claim 5, wherein the circuit layer further comprises an inorganic auxiliary insulating layer between the first source-drain conductive layer and the first planarization layer, and comprising an inorganic insulating material,
wherein the first encapsulation layer is in contact with the inorganic auxiliary insulating layer through bonding grooves penetrating the second common layer and the second electrode, and
wherein the bonding grooves are located in a separation area between the two or more light transmitting peripheral dams, and on opposite sides of the two or more light transmitting peripheral dams.

8. The display device of claim 4, wherein the circuit layer further comprises:
a second semiconductor layer on the first interlayer insulating layer;
a third gate insulating layer covering the second semiconductor layer;
a third gate conductive layer on the third gate insulating layer; and
a second interlayer insulating layer covering the third gate conductive layer,
wherein the first source-drain conductive layer and the first planarization layer are located on the second interlayer insulating layer,
wherein each of the third gate insulating layer and the second interlayer insulating layer comprises an inorganic insulating material,
wherein the shield line is located in the third gate conductive layer,
wherein the first encapsulation layer is in contact with the second interlayer insulating layer through bonding grooves penetrating the second common layer and the second electrode, and
the bonding grooves are located in a separation area between the two or more light transmitting peripheral dams, and on opposite sides of the two or more light transmitting peripheral dams.

9. The display device of claim 8, wherein the shield line comprises:
a first shield layer located in the third gate conductive layer; and
at least one second shield layer located in the first source-drain conductive layer, and electrically connected to the first shield layer, and
wherein the two or more light transmitting peripheral dams cover the at least one second shield layer.

10. The display device of claim 8, wherein the circuit layer further comprises bonding auxiliary layers located in the separation area between the two or more light transmitting peripheral dams, and on the opposite sides of the two or more light transmitting peripheral dams,
wherein the bonding auxiliary layers are located on the second interlayer insulating layer of the light transmitting peripheral area,
wherein the bonding grooves overlap with the bonding auxiliary layers, and
wherein the first encapsulation layer is in contact with the bonding auxiliary layers through the bonding grooves.

11. The display device of claim 4, wherein the circuit layer further comprises:
a second semiconductor layer on the first interlayer insulating layer;
a third gate insulating layer covering the second semiconductor layer;
a third gate conductive layer on the third gate insulating layer;
a second interlayer insulating layer covering the third gate conductive layer; and
bonding auxiliary layers located in a separation area between the two or more light transmitting peripheral dams, and on opposite sides of the two or more light transmitting peripheral dams,
wherein the first source-drain conductive layer and the first planarization layer are located on the second interlayer insulating layer,
wherein each of the third gate insulating layer and the second interlayer insulating layer comprises an inorganic insulating material,
wherein the shield line is located in the third gate conductive layer,
wherein each of the bonding auxiliary layers has an undercut structure comprising a main layer on the second interlayer insulating layer of the light transmitting peripheral area, and a roof layer on the main layer and protruding beyond the main layer, and
wherein the first encapsulation layer is in contact with a portion of a side surface of the main layer adjacent to the roof layer in each of the two or more bonding auxiliary layers.

12. The display device of claim 3, wherein the first encapsulation layer and the third encapsulation layer extend to at least a part of the light transmitting area,
wherein the third encapsulation layer is in contact with the first encapsulation layer in at least a part of the light transmitting area, and
wherein the first encapsulation layer is in contact with the support substrate through the light transmitting hole.

13. The display device of claim 12, wherein the light transmitting hole comprises:
a first hole penetrating the second common layer and the second electrode; and
a second hole penetrating the first encapsulation layer and the third encapsulation layer, and
wherein the filling layer is in contact with the support substrate through the light transmitting hole.

14. The display device of claim 3, wherein the filling layer comprises:
a first filling portion overlapping with the display area and the light transmitting peripheral area, and comprising a first transparent material; and
a second filling portion overlapping with the light transmitting area, and comprising a second transparent material having a higher refractive index than that of the first transparent material.

15. The display device of claim 3, further comprising a light blocking bank located between the first substrate and the second substrate, surrounding around the light transmitting area, and overlapping with the two or more light transmitting peripheral dams,
wherein the light blocking bank comprises at least one of a light blocking material to block light, a light absorbing material to absorb light, or a transparent material having a higher refractive index than that of the filling layer.

16. An electronic device comprising:
a display device configured to display an image;
a memory configured to store an application;
a processor configured to execute the application, and transmit an image data signal and an input control signal to the display device; and
a power module configured to transmit power to the display device,
wherein the display device comprises:
a first substrate;
a second substrate facing and bonded to the first substrate, each of the first substrate and the second substrate comprising:
a display area comprising emission areas;
a non-display area around the display area;
a light transmitting area surrounded around by the display area; and
a light transmitting peripheral area between the light transmitting area and the display area; and
a filling layer filled between the first substrate and the second substrate,
wherein the first substrate further comprises:
a support substrate;
a circuit layer on the support substrate; and
two or more light transmitting peripheral dams in the light transmitting peripheral area, and spaced from each other,
wherein the circuit layer comprises:
light emitting pixel drivers along a first direction and a second direction in the display area;
data lines extending in the second direction, and configured to transmit data signals to the light emitting pixel drivers; and
a shield line in the light emitting peripheral area, and configured to transmit a constant voltage,
wherein the data lines comprise:
intersecting data lines; and
normal data lines spaced from the light transmitting area and the light transmitting peripheral area in the first direction,
wherein each of the intersecting data lines comprises:
a bypass data line overlapping with the light emitting peripheral area;
a first divided data line facing one side of the light transmitting peripheral area in the second direction; and
a second divided data line facing another side of the light transmitting peripheral area in the second direction, and electrically connected to the first divided data line through the bypass data line,
wherein the shield line overlaps with the bypass data lines of the intersecting data lines in a third direction, and
wherein the two or more light transmitting peripheral dams overlap with the shield line in the third direction.

17. The electronic device of claim 16, wherein the circuit layer further comprises:
a first semiconductor layer on the support substrate;
a first gate insulating layer covering the first semiconductor layer;
a first gate conductive layer on the first gate insulating layer;
a second gate insulating layer covering the first gate conductive layer;
a second gate conductive layer on the second gate insulating layer;
a first interlayer insulating layer covering the second gate conductive layer;
a first source-drain conductive layer on the first interlayer insulating layer;
a first planarization layer covering the first source-drain conductive layer;
a second source-drain conductive layer on the first planarization layer; and
a second planarization layer covering the second source-drain conductive layer,
wherein each of the first gate insulating layer, the second gate insulating layer, and the interlayer insulating layer comprises an inorganic insulating material,
wherein each of the normal data lines, the first divided data lines of the intersecting data lines, and the second divided data lines of the intersecting data lines is located in the second source-drain conductive layer, and
wherein each of the bypass data lines is located in one of the first gate conductive layer or the second gate conductive layer.

18. The electronic device of claim 17, wherein the first substrate further comprises:
an element layer on the circuit layer;
an encapsulation layer covering the element layer; and
a light transmitting hole overlapping with the light transmitting area,
wherein the element layer comprises:
first electrodes in the emission areas, and electrically connected to the light emitting pixel drivers, respectively;
a pixel defining layer in a non-emission area between the emission areas of the display area, and covering edges of the first electrodes;
first common layers on the first electrodes;
light emitting layers on the first common layers;
a second common layer on the pixel defining layer and the light emitting layers; and
a second electrode on the second common layer,
wherein the encapsulation layer comprises:
a first encapsulation layer on the element layer, and comprising an inorganic insulating material;
a second encapsulation layer on the first encapsulation layer, and comprising an organic insulating material; and
a third encapsulation layer covering the second encapsulation layer, and comprising an inorganic insulating material,
wherein the second encapsulation layer is spaced from the light transmitting area by the two or more light transmitting peripheral dams,
wherein the light transmitting hole penetrates the second common layer and the second electrode, and
wherein, in a portion of the light transmitting peripheral area between the two or more light transmitting peripheral dams and the light transmitting area, the third encapsulation layer is in contact with the first encapsulation layer.

19. The electronic device of claim 18, wherein the circuit layer further comprises an inorganic auxiliary insulating layer between the first source-drain conductive layer and the first planarization layer, and comprising an inorganic insulating material,
wherein the shield line is located in the first source-drain conductive layer,
wherein the first encapsulation layer is in contact with the inorganic auxiliary insulating layer through bonding grooves penetrating the second common layer and the second electrode, and
wherein the bonding grooves are located in a separation area between the two or more light transmitting peripheral dams, and on opposite sides of the two or more light transmitting peripheral dams.

20. The electronic device of claim 18, wherein the circuit layer further comprises:
a second semiconductor layer on the first interlayer insulating layer;
a third gate insulating layer covering the second semiconductor layer;
a third gate conductive layer on the third gate insulating layer; and
a second interlayer insulating layer covering the third gate conductive layer,
wherein the first source-drain conductive layer and the first planarization layer are on the second interlayer insulating layer,
wherein each of the third gate insulating layer and the second interlayer insulating layer comprises an inorganic insulating material,
wherein the shield line is located in the third gate conductive layer,
wherein the first encapsulation layer is in contact with the second interlayer insulating layer through bonding grooves penetrating the second common layer and the second electrode, and
wherein the bonding grooves are located in a separation area between the two or more light transmitting peripheral dams, and on opposite sides of the two or more light transmitting peripheral dams.
